(19) United States
(12) Patent Application Publication
(10) Pub. No.: US 2023/0420333 A1
(43) Pub. Date: Dec. 28, 2023

(54) SUBSTRATE FEATURES IN THERMALLY CONDUCTIVE MATERIALS

(71) Applicant: Akash Systems, Inc., San Francisco, CA (US)

(72) Inventors: Daniel FRANCIS, San Francisco, CA (US); Frank LOWE, San Francisco, CA (US); Kyle GRAHAM, San Francisco, CA (US)

(21) Appl. No.: 18/465,017

(22) Filed: Sep. 11, 2023

Related U.S. Application Data
(63) Continuation of application No. PCT/US2022/019943, filed on Mar. 11, 2022.
(60) Provisional application No. 63/160,058, filed on Mar. 12, 2021.

(51) Int. Cl. H01L 23/373; H01L 21/02

(52) U.S. Cl. CPC H01L 23/3732; H01L 21/02527; H01L 21/02381; H01L 21/0262; H01L 21/02645

(57) ABSTRACT

Aspects of features in thermally conductive substrates and methods of forming the same are described. A substrate may comprise a material having an average value of thermal conductivity equal to or greater than about 1,000 W/mK. The substrate may comprise diamond. The substrate may comprise a wide-bandgap semiconductor material. A feature may comprise an interconnect, such as a via hole. A feature may comprise a singulation feature, such as a die street. The substrate may comprise a plurality of crystals each having an average crystal grain diameter from about 10 nanometers to about 100 nanometers. The plurality of crystals may be disposed a distance of less than or equal to about 100 micrometers from a surface of the feature. The substrate may comprise a keyhole or void. The keyhole may be disposed a distance of less than or equal to about 100 micrometers from a surface of the feature.

### CROSS-REFERENCE

This application is a Continuation of PCT Application No. PCT/US2022/019943 filed Mar. 11, 2022 which claims the benefit of U.S. Provisional Patent Application Ser. No. 63/160,058 filed Mar. 12, 2021, which is incorporated herein by reference in its entirety for all purposes.

### BACKGROUND

As development of wide-bandgap semiconductor devices continues to evolve, the demand for efficiency increases. Semiconductor devices such as power amplifiers can exhibit improved thermal efficiencies and operating temperatures with improved performance and reliability through the use of wide-bandgap semiconductors.

### SUMMARY

The integration of thermally conductive materials, such as diamond heat-sinks or diamond substrates with wide-bandgap semiconductors has helped drive improvements in thermal efficiency for substrates. However, generating substrate features or features such as vias, through holes, die streets, trenches and channels in substrates and films may be difficult and time-consuming, particularly for substrates and films comprising hard and chemically inert materials. Additionally, challenges exist in generating features while avoiding damage to components proximate to features or avoiding device performance degradation. To improve the thermal efficiencies of wide-bandgap semiconductor devices, particularly for high-power and high-frequency applications, it may be desirable to integrate high-thermal conductivity materials, such as diamond, with semiconductor materials. However, challenges arise in generating features or substrate features in substrates comprising thermally conductive materials.

Examples of the present disclosure provide apparatuses and methods of generating features in substrates comprising thermally conductive materials. High-thermal conductivity substrates, for example, may comprise hard and chemically inert materials. Such substrates may include materials having average thermal conductivities equal to or greater than about 1,000 W/mK. Standard processing methods of generating features, for example, including etching and drilling, may be impracticable for use directly on such thermally conductive materials, given the hardness and chemical inertness of such materials. Additionally, such standard processing methods may lead to heat damage or performance degradation of devices or device components proximate to features.

In an aspect, a semiconductor structure is provided. A semiconductor structure may comprise: a layered structure comprising a semiconductor material; a layer of material on the layered structure; and a substrate feature extending into at least a portion of the layer of material, wherein a region of the layer of material in proximity to the substrate feature comprises a plurality of crystals having an average grain size or an average grain density that is different from another region of the layer of material that is further away from the substrate feature than the region.

In some embodiments, at least a portion of the plurality of crystals is at a distance of less than or equal to about 100 micrometers from the substrate feature. In some embodiments, the substrate feature is an interconnect. In some embodiments, at least a portion of the plurality of crystals is at a distance of less than or equal to about 100 micrometers from an edge of the semiconductor structure. In some embodiments, the layer of material comprises a keyhole. In some embodiments, the keyhole is disposed within the layer of material at a distance of less than or equal to about 100 micrometers from the substrate feature. In some embodiments, the average grain size of the plurality of crystals increases with distance in a direction away from the substrate feature. In some embodiments, the direction is perpendicular to a surface of the substrate feature, wherein the average grain size of the plurality of crystals increases proportionally with said distance in said direction.

In some embodiments, a region of the layer of material in proximity to an interface between the layer of material and the layered structure comprises a plurality of crystals having an average grain size or an average grain density that is different from another region of the layer of material that is further away from the interface. In some embodiments, at least a portion of the plurality of crystals is at a distance of less than or equal to about 100 micrometers from the interface. In some embodiments, the average grain size of the plurality of crystals increases with distance in a direction away from the interface. In some embodiments, the average grain size of the plurality of crystals increases in a direction parallel to a surface of the substrate feature. In some embodiments, at least a portion of the plurality of crystals forms a surface adjacent to the substrate feature having a surface roughness from about 20 nanometers to about 10 microns. In some embodiments, at least a portion of the surface comprises a plurality of voids in the material. In some embodiments, a diameter of the plurality of voids varies in proportion with the average grain size of the material.

In some embodiments, the average grain size is an average crystal grain diameter, and the average crystal grain diameter of the plurality of crystals is from about 10 nanometers to about 2,000 nanometers. In some embodiments, the semiconductor material is a wide-bandgap semiconductor material. In some embodiments, the substrate feature is a die street. In some embodiments, the substrate feature is at the edge of the semiconductor structure.

In some embodiments, the semiconductor structure further comprises at least one device on the layered structure or the layer of material. In some embodiments, the at least one device is at a distance less than or equal to about 100 micrometers from the substrate feature. In some embodiments, the layer of material comprises diamond. In some embodiments, the semiconductor material comprises one or more materials selected from the group consisting of GaN, AlN, InGaN, InAlN, AlGaN, InGaAlN, Ga2O3, ScAlN and derivatives or combinations thereof. In some embodiments, the substrate feature comprises silicon. In some embodiments, the layer of material has an average value of thermal conductivity equal to or greater than about 1,000 Watts per meter Kelvin (W/mK). In some embodiments, the substrate feature is a via. In some embodiments, the substrate feature is a trench.

In an aspect, a method for generating a layer of diamond comprising a hole is provided. The method may comprise: (a) providing a support and a post over said support; (b) growing a layer of diamond over said support, wherein said layer of diamond circumscribes said post; and (c) removing said post, thereby yielding said layer of diamond comprising said hole.

In an aspect, a method is provided. The method may comprise: (i) providing a first semiconductor material layer and a second semiconductor material layer; (ii) etching the second semiconductor material layer to form a feature mold; (iii) generating, over a surface of the first semiconductor material, a layer of material; and (iv) etching at least a portion of the feature mold to generate a substrate feature comprising a hollow region, wherein a region of the layer of material in proximity to the substrate feature comprises a plurality of crystals having an average grain size or an average grain density that is different from another region of the layer of material that is further away from the substrate feature than the region.

In some embodiments, the substrate feature extends into a portion of the layer of material. In some embodiments, the substrate feature comprises a non-etched portion of the feature mold. In some embodiments, the substrate feature further extends through a portion of the first semiconductor material layer. In some embodiments, the layer of material is generated adjacent to at least one surface of the feature mold. In some embodiments, the layer of material comprises an average value of thermal conductivity equal to or greater than 1,000 W per meter Kelvin. In some embodiments, at least a portion of the plurality of crystals is at a distance of less than or equal to about 100 micrometers from the substrate feature. In some embodiments, at least a portion of the plurality of crystals is at a distance of less than or equal to about 100 micrometers from an edge of the substrate.

In some embodiments, (iii) comprises forming at least one keyhole in the layer of material. In some embodiments, the keyhole is formed a distance of less than or equal to about 100 micrometers from the substrate feature. In some embodiments, the average grain size of the plurality of crystals increases with distance in a direction away from the substrate feature. In some embodiments, at least a portion of the plurality of crystals is at a distance of less than or equal to about 100 micrometers from the interface. In some embodiments, the average grain size of the plurality of crystals increases with distance in a direction away from the interface. In some embodiments, the average grain size of the plurality of crystals increases in a direction parallel to a surface of the substrate feature. In some embodiments, at least a portion of the plurality of crystals forms a surface adjacent to the substrate feature having a surface roughness from about 20 nanometers to about 10 microns. In some embodiments, at least a portion of the surface comprises a plurality of voids in the material. In some embodiments, a diameter of the plurality of voids varies in proportion with the average grain size of the material.

In some embodiments, the generating the layer of material comprises selective area growth around the feature mold. In some embodiments, the average grain size is an average crystal grain diameter, and wherein the average crystal grain diameter of the plurality of crystals is from about 10 nanometers to about 2,000 nanometers. In some embodiments, the substrate feature comprises silicon. In some embodiments, the method further comprises plating at least a portion of the substrate feature with a metal layer. In some embodiments, the first semiconductor material comprises one or more materials selected from the group consisting of GaN, AlN, InGaN, InAlN, AlGaN, InGaAlN, Ga2O3, ScAlN and derivatives or combinations thereof. In some embodiments, the second semiconductor material comprises silicon. In some embodiments, the layer of material comprises diamond.

In some embodiments, the method further comprises providing at least one device on the substrate at a distance less than or equal to about 100 micrometers from the substrate feature. In some embodiments, the method further comprises etching at least a portion of the first semiconductor material layer or the second semiconductor material layer. In some embodiments, (iii) further comprises generating, over the surface of the feature mold, a layer of material. In some embodiments, the method further comprises seeding a layer of diamond over at least a portion of the first semiconductor material substantially without seeding a wall of the feature mold. In some embodiments, the method further comprises seeding a layer of diamond over at least a portion of a wall of the feature mold substantially without seeding the first semiconductor material. In some embodiments, the method further comprises seeding a layer of diamond over at least a portion of a wall of the feature mold and at least a portion of the first semiconductor material.

In an aspect, a semiconductor structure is provided. The semiconductor structure may comprise: a layered structure comprising a semiconductor material; a layer of material on the layered structure, wherein the layer of material has an average value of thermal conductivity equal to or greater than about 1,000 Watts per meter Kelvin (W/mK); and a substrate feature extending through at least a portion of the layer of material, wherein a region of the layer of material in proximity to the substrate feature comprises a plurality of crystals having an average grain size or an average grain density that is different from another region of the layer of material that is further away from the substrate feature.

In some embodiments, the average grain size is an average crystal grain diameter, and the average crystal grain diameter of the plurality of crystals is from about 10 nanometers to about 2,000 nanometers. In some embodiments, at least a portion of the plurality of crystals is at a distance of less than or equal to about 100 micrometers from the substrate feature. In some embodiments, at least a portion of the plurality of crystals is at a distance of less than or equal to about 100 micrometers from an edge of the semiconductor structure. In some embodiments, the layer of material comprises a keyhole. In some embodiments, the keyhole is disposed within the layer of material at a distance of less than or equal to about 100 micrometers from the substrate feature.

In some embodiments, the average grain size of the plurality of crystals increases with distance in a direction away from the substrate feature. In some embodiments, the semiconductor material is a wide-bandgap semiconductor material. In some embodiments, the substrate feature is an interconnect. In some embodiments, the substrate feature is a die street. In some embodiments, the substrate feature is at the edge of the semiconductor structure. In some embodiments, the semiconductor structure further comprises at least one device on the layered structure or the layer of material. In some embodiments, the at least one device is at a distance less than or equal to about 100 micrometers from the substrate feature. In some embodiments, the layer of material comprises diamond. In some embodiments, the semiconductor material comprises one or more materials selected from the group consisting of GaN, AlN, InGaN, InAlN, AlGaN, InGaAlN, Ga2O3, ScAlN and derivatives or combinations thereof. In some embodiments, the substrate feature comprises silicon.

In an aspect, a method is provided. The method comprises: (i) providing a substrate having a first semiconductor material layer and a second semiconductor material layer; (ii) etching the second semiconductor material layer to form a feature mold; (iii) generating, over a surface of the substrate and the feature mold, a layer of material having an average value of thermal conductivity equal to or greater than about 1,000 Watts per meter Kelvin (W/mK); and (iv) etching at least a portion of the feature mold to generate a substrate feature comprising a hollow region.

In some embodiments, the substrate feature extends through a portion of the layer of material. In some embodiments, the substrate feature comprises a non-etched portion of the feature mold. In some embodiments, the substrate feature further extends through a portion of the first semiconductor material layer. In some embodiments, the layer of material is generated adjacent to at least one surface of the feature mold. In some embodiments, a region of the layer of material in proximity to the substrate feature comprises a plurality of crystals having an average grain size or an average grain density that is different from another region of the layer of material that is further away from the substrate feature. In some embodiments, the average grain size is an average crystal grain diameter and the average crystal grain diameter of the plurality of crystals is from about 10 nanometers to about 2,000 nanometers. In some embodiments, at least a portion of the plurality of crystals is at a distance of less than or equal to about 100 micrometers from the substrate feature.

In some embodiments, at least a portion of the plurality of crystals is at a distance of less than or equal to about 100 micrometers from an edge of the substrate. In some embodiments, generating the layer of material comprises forming at least one keyhole in the layer of material. In some embodiments, the keyhole is formed a distance of less than or equal to about 100 micrometers from the substrate feature. In some embodiments, the average grain size of the plurality of crystals increases with distance in a direction away from the substrate feature. In some embodiments, the substrate feature comprises silicon. In some embodiments, the method further comprises plating at least a portion of the substrate feature with a metal layer. In some embodiments, the first semiconductor material comprises one or more materials selected from the group consisting of GaN, AlN, InGaN, InAlN, AlGaN, InGaAlN, Ga2O3, ScAlN and derivatives or combinations thereof. In some embodiments, the second semiconductor material comprises silicon. In some embodiments, the layer of material comprises diamond. In some embodiments, the method further comprises providing at least one device on the substrate at a distance less than or equal to about 100 micrometers from the substrate feature. In some embodiments, the direction is perpendicular to a surface of the substrate feature, wherein the average grain size of the plurality of crystals increases proportionally with said distance in said direction.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which various principles of the invention are utilized, and the accompanying drawings or figures (also “FIG.” and “FIGS.” herein), of which:

FIG. 1A, FIG. 1B, FIG. 1C, and FIG. 1D illustrate cross-sectional views of example substrates, in accordance with some embodiments disclosed herein.

FIG. 2A, FIG. 2B, FIG. 2C, and FIG. 2D illustrates a cross-sectional view of an example substrate, in accordance with some embodiments disclosed herein.

FIG. 3A, FIG. 3B, FIG. 3C, FIG. 3D, FIG. 3E, FIG. 3F, FIG. 3G, FIG. 3H, FIG. 3I, FIG. 3J, FIG. 3K, and FIG. 3L illustrate a cross-sectional view of an example method of forming a feature, in accordance with some embodiments disclosed herein.

FIG. 4 illustrates generally a flowchart of an example method of forming a feature, in accordance with some embodiments disclosed herein.

FIG. 5A, FIG. 5B, FIG. 5C, FIG. 5D, and FIG. 5E illustrates generally a top-down view of an example method of forming a feature, in accordance with some embodiments disclosed herein.

FIG. 6A, FIG. 6B, FIG. 6C, FIG. 6D, and FIG. 6E illustrates generally a top-down view of another example method of forming a feature, in accordance with some embodiments disclosed herein.

FIG. 7 illustrates generally a computer system that can be programmed or otherwise configured to form a feature, in accordance with some examples.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

It shall be understood that different aspects of the invention can be appreciated or modified individually, collectively, or in combination with each other. Where values are described as ranges, it will be understood that such disclosure includes the disclosure of all possible sub-ranges within such ranges, as well as specific numerical values that fall within such ranges irrespective of whether a specific numerical value or specific sub-range is expressly stated.

As recognized herein, generating features in substrates or substrate features may be extremely challenging when a substrate comprises physically hard or chemically inert materials. Examples of such materials may include materials having average thermal conductivities equal to or greater than about 1,000 Watts per meter Kelvin (W/mK) in at least a single dimension. Some examples may include diamond (e.g., synthetic diamond). Such substrates may be impervious to wet chemical or plasma etching and may be resistant to laser drilling, mechanical drilling and micromachining. Additionally, certain techniques, including laser ablation, may heat such substrates to temperatures that can damage surrounding components or materials. In addition to the foregoing challenges, such techniques can introduce lengthy processing times, which may negatively impact device production cycle. While high-energy plasma may be used to overcome high covalent bond strengths in certain substrate materials (e.g., to enable wafer scale etching of features in a substrate), the combination of high energy and slow etch speed may lead to poor etch selectivity. For example, a photomask defining a feature pattern may degrade or etch away during an etching process of substrates comprising materials that may be chemically inert. In such cases, mask patterns may be thick and robust to withstand degradation during etching, which may lead to extra processing steps, longer processing times and larger feature sizes.

The present disclosure provides solutions to the foregoing challenges and provides methods of manufacturing features in substrates or films comprising hard materials, chemically inert materials, or a combination thereof. Such methods may reduce or eliminate damage to components, devices or materials proximate to the features. Such methods may reduce manufacturing time and complexity of generating the features in the disclosed substrates. Such methods may improve etch selectivity in manufacturing the disclosed features. Examples of the present disclosure provide apparatuses, devices and systems comprising features with improved average feature sizes compared to apparatuses manufactured according to standard processing methods. Examples provide improved average aspect ratios. Examples provide improved average etch angles. Examples provide features that may be disposed closer to substrate components or devices compared to standard methods.

Unless otherwise defined, all technical terms used herein have the same meaning as commonly understood by one of ordinary skill in the art to which this invention belongs. As used in this specification and the appended claims, the singular forms “a,” “an,” and “the” include plural references unless the context clearly dictates otherwise. Any reference to “or” herein is intended to encompass “and/or” unless otherwise stated.

The term “wide-bandgap” and “wide-gap” (or variations thereof), as used herein in the context of semiconductor technology, generally refer to electronic and/or optoelectronic devices and manufacturing technologies based on wide-bandgap semiconductors. A wide-bandgap semiconductor may have a bandgap in a range of 2-4 electronvolt (eV), for example. A wide-bandgap semiconductor may have a bandgap in a range greater than about 3.4 eV. A wide-bandgap semiconductor can comprise, for example, in relation to the Periodic Table of the Elements: (a) semiconductors comprising a bond between nitrogen (N) and at least one Group III element, (b) semiconductors comprising a bond between carbon (C) and at least one Group IV element, or (c) semiconductors comprising a bond between oxygen (O) and at least one Group II element. A wide-bandgap semiconductor, for example, may comprise one or more materials including gallium, aluminum, indium, boron, scandium, nitrogen, and derivatives thereof. In some examples, a wide-bandgap semiconductor may include gallium nitride (GaN), aluminum nitride (AlN), indium gallium nitride (InGaN), indium aluminum nitride (InAlN), aluminum gallium nitride (AlGaN), indium gallium aluminum nitride (InGaAlN), gallium oxide (Ga2O3) or derivatives thereof. Such materials may improve performance efficiency in high-power microwave devices, which can exhibit electron mobilities, breakdown voltages, and thermal conductivities that exceed other semiconductor materials, such as gallium arsenide (GaAs), indium phosphide (InP), or silicon.

The term “thermal budget,” as used herein, generally refers to an assessment of temperature dissipation from one or more components to an environment. For example, a thermal budget may define an amount of thermal energy transferred from a heat source (e.g., active layers of a device) to a surrounding environment. The active layers of a semiconductor device may be several micrometers thick and may be disposed adjacent to mechanical carriers or substrates.

The term “substrate,” as used herein, generally refers to any substance upon which a structure (e.g., layered structure) may be deposited. The substrate may comprise a foundation for the fabrication of electronic devices, such as transistors, diodes, and integrated circuits. The substrate may comprise a solid material such as a semiconductor or an insulator. Substrate materials may comprise one or more of, for example, carbon, aluminum, gallium, silicon, germanium, arsenic, thallium, cadmium, tellurium, selenium, or alloy or allotrope thereof, or an oxide or nitride thereof. The substrate may be a carbon-containing substrate or a semiconductor-containing substrate. The substrate may include one or more chemical dopants, for example, nitrogen, phosphorous, boron or indium. Substrate materials may comprise one or more of, for example, diamond, synthetic diamond, silicon (Si), silicon dioxide (SiO₂), silicon carbide (SiC), aluminum oxide (Al₂O₃), sapphire, aluminum nitride (AlN), scandium aluminum nitride (ScAlN), germanium, gallium arsenide, gallium nitride (GaN), or indium phosphide (InP), indium nitride (InN), aluminum gallium nitride (AlGaN), indium gallium nitride (InGaN), indium aluminum nitride (InAlN), zinc oxide (ZnO), for example. The substrate may include carbon-containing materials such as diamond, synthetic diamond, diamond-like carbon (DLC), diamond nanoparticles (e.g., nanodiamond), graphite, graphene, etc. The substrate may include a material having a thermal conductivity (W/mK). Thermal conductivity, or the measurement of the ability of a material to conduct heat, may be measured and quantified as an average value. For example, a substrate may include a material having a thermal conductivity equal to or greater than about 1,000 W/mK (e.g., in at least a single dimension). The average thermal conductivity of such substrate may be greater than at least about 500 W/mK, 1,000 W/mK, 1,500 W/mK, 2,000 W/mK, 2,500 W/mK, 3,000 W/mK or greater. The average thermal conductivity may be within a range from about 500 W/mK to about 2,000 W/mK. The average thermal conductivity may be within a range from about 500 W/mK to about 3,000 W/mK. The average thermal conductivity may be within a range from about 1,500 W/mK to about 2,500 W/mK. Such materials may be “high-thermal conductivity” materials. The substrate may include a wide-bandgap semiconductor. The substrate material may be single crystalline, poly crystalline, amorphous or a combination thereof. The substrate may comprise a buffer layer. The substrate may comprise a barrier layer. The substrate may comprise a buffer layer disposed adjacent to the barrier layer. An intermediate layer may be disposed between the buffer layer and the barrier layer. The buffer layer may comprise a wide-bandgap semiconductor. The buffer layer may comprise a Group III element and a Group V element. The barrier layer may comprise a wide-bandgap semiconductor. The barrier layer may comprise a Group III element and a Group V element. The barrier layer may comprise a source region and a drain region. The buffer layer and the barrier layer may include a channel between the source region and the drain region.

The term “single-crystal,” as used herein, generally refer to a material having one crystal or having a translational symmetry. The term “polycrystalline” generally refers to a material having more than one crystal domain or orientation. A polycrystalline material may exhibit more than one crystal structure under low energy electron diffraction (LEED) microscopy. The term “amorphous” generally refers to a material having no real or apparent crystalline form. An amorphous material may not exhibit any long-range crystal structure under LEED.

Active layers of a semiconductor device may be epitaxially grown on a substrate. In some cases, the substrate may be of the same family of materials as the active layers of the electronic device. Electronic materials for device fabrication may be realized by attaching the active layers to substrates comprising materials having crystalline structures and material combinations different from the active layer. Examples of ways to attach semiconductors to substrates having different crystal structures can include direct-bonding or direct growth using transition layer(s) to bridge different lattice structures. Alternatives to bonding and die-attachment may include the use of selective area deposition (SAD).

The substrate may have various functions, for example, (i) mechanical support; (ii) electrical conductivity that can be used to connect the active layers to the bottom of the chip; (iii) electrical isolation with low dielectric losses that can be used in high-frequency devices and surface waveguides where electric fields penetrate into the substrate; and (iv) high thermal conductivity with or without associated electrical conductivity.

The term “layered structure,” as used herein, generally refers to structures created from layers of materials of varying properties. A layered structure may comprise layers of the same or varying semiconductor properties. Individual layers may be single crystalline or polycrystalline. Individual layers may be amorphous. Electronic and optoelectronic devices manufactured out of layers of different semiconductors may be made by different growth techniques. In some cases, these growth techniques may allow for controlled growth of individual layers. In some case, the layers may be referred to as “epitaxial layers” or “epilayers.” Each layer may be of a thickness varying from sub-nanometer to tens of microns. Each layer may be of a thickness between 1 nanometer (nm) and 50 nm, between 10 nm and 100 nm, etc. Each layer may be greater than 1 nm, 2 nm, 5 nm, greater than 10 nm, 20 nm, greater than 50 nm, greater than 100 nm, greater than 1 micron or greater. Each layer may be less than 1 micron, less than 100 nm, less than 50 nm, less than 20 nm, less than 10 nm, less than 5 nm, less than 2 nm, less than 1 nm, or less. Each layer may be atomically thin. Non-limiting examples of manufacturing techniques include molecular beam epitaxy (MBE), chemical vapor deposition (CVD), atomic layer deposition (ALD), physical vapor deposition, organo-metallic vapor-phase epitaxy, and liquid phase epitaxy.

A substrate may comprise a thickness of at least about 1 micron, at least about 10 microns, at least about 50 microns, at least about 100 microns, at least 1 about millimeter or greater. A substrate may comprise a thickness of at least 1 millimeter of diamond. A substrate may comprise a thickness of diamond within a range from about 1 micron to about 1 millimeter, within a range from about 10 microns to about 1 millimeter, within a range from about 50 microns to about 1 millimeter or within a range from about 100 microns to about 500 microns. A substrate may comprise a thickness of about 100 microns, about 105 microns, about 110 microns, about 125 microns, about 150 microns, or greater.

Epitaxial layers may comprise one or more of, for example, boron, aluminum, gallium, indium, thallium, carbon, silicon, germanium, tin, lead, nitrogen, phosphorous, arsenic, antimony, bismuth, oxygen, sulfur, selenium, tellurium, beryllium, magnesium, calcium, zinc, cadmium, scandium, and alloys and allotropes thereof or an oxide or nitride thereof. Epitaxial layers may comprise a semiconductor comprising a bond between at least one Group III element and at least one Group V element. Epitaxial layers may comprise semiconductors comprising a bond between nitrogen and at least one Group III element (e.g., boron, aluminum, gallium, indium, thallium, scandium), semiconductors comprising a bond between multiple oxygen and at least one Group III element (e.g., Gallium Oxide (Ga₂O₃, Aluminum Oxide (Al₂O₃)), semiconductors comprising a bond between carbon and at least one group IV element (e.g., carbon, silicon, germanium, tin, lead), and semiconductors comprising a bond between oxygen and at least one group II element (e.g., beryllium, magnesium, calcium, zinc, cadmium). Epitaxial layers may comprise one or more wide-bandgap semiconductors. Epitaxial layers may comprise one or more of, for example, GaN, Ga₂O₃, AlN, Al₂O₃, InN, AlGaN, InGaN, InAlN, ZnO, SiC, and diamond. Any of the above materials may be single-crystalline, polycrystalline, or amorphous.

A substrate may comprise a comprise a two-dimensional electron gas layer (2DEG layer), which may be embedded within a layered structure. A 2DEG layer may be embedded within a buffer layer. A 2DEG layer may be proximate to an interface between a barrier layer and a buffer layer. A 2DEG layer may have a width of less than 50 nm, less than 10 nm, or less than 5 nm. A 2DEG layer, for example, may be no further than 150 nm, no further than 250 nm, no further than 500 nm, no further than 750 nm, no further than 1 micron, or no further than 100 microns, from an interface between a layered structure and a carbon-containing substrate (e.g., diamond substrate).

The term “chip,” as used herein generally refers to an active electronic or optoelectronic device, which may be disposed on a substrate. A chip may comprise one or more active layers disposed a substrate. The chip may comprise a layered structure. The chip may comprise one or more transistors (e.g., field-effect transistor, bipolar transistor). A transistor may be a high-electron-mobility transistor. The chip may comprise an integrated circuit, such as a monolithic microwave integrated circuit (MMIC). The chip may perform functions such as mixing, power amplification, low noise amplification, and switching.

The term “transistor,” as used herein, generally refers to an electrical device which can act as a switch and/or an amplifier. A transistor may be a part of a digital circuit. A digital circuit may comprise a plurality of transistors. A transistor may comprise one or more contacts, a layered structure, and a substrate. A transistor may be a part of a computing device. A transistor may be a portion of a logic circuit or a logic gate. A transistor may be a semiconductor device. The term “field-effect transistor” (FET) as used herein, generally refers to a transistor which uses an electric field to control the operation of a device having the transistor. An electric field may be used to control the flow of current between two contacts or terminals in the device such as a source contact and a drain contact.

The term “high-electron-mobility transistor” (HEMT), as used herein, generally refers to a field-effect transistor comprising a heterojuction. A high-electron-mobility transistor may be alternatively referred to as a heterostructure field effect transistor. The term “heterojuction,” as used herein, may refer to the interface between any two solid-state materials of differing material properties. In some examples, these may include any two semiconductors, any two crystalline forms (e.g., amorphous, polycrystalline) of the same semiconductor, any two semiconductors comprising the same element but with varying amounts of those elements, any two semiconductors with varying dopant level, etc. The two materials may have unequal band gaps. The two materials may have a band offset. The two materials forming the heterojuction may be referred to as a “heterostructure.” In some examples, an interface between a buffer layer and a barrier layer may form a heterojunction.

The term “Schottky contact,” as used herein, generally refers to a metal-semiconductor interface with a non-zero contact resistance, measured relative to the resistance of the semiconductor. The contact may comprise an energetic barrier between states of the semiconductor and states of the metal which barrier may be non-zero. The contact may be a rectifying contact, e.g., a Schottky barrier. In some examples, devices may include one or more dielectric or insulating material layers, for example, under a gate contact. Such devices may comprise Metal-Insulator-Semiconductor Field Effect Transistors (“MISFET”s).

The term “interface,” as used herein, generally refers to a surface forming a common boundary between two different materials, for example, materials having differing crystalline structures, differing material combinations, differing material properties. The term “interface” can refer to a location where two different materials come into contact with one another. The term “interface” can also refer to the atoms of a first material combining with the atoms of a second material at a location or at a boundary, for example, without the presence of atoms of a third material. An interface may be a surface forming a common boundary between semiconductor and diamond. An interface can be a location where diamond atoms contact atoms of a wide-bandgap semiconductor. A compound substrate of the present disclosure may include a single interface. In some examples, such compound substrate may not include more than one interface.

The term “etching,” as used herein, generally refers to a process of removing (e.g., via chemical, plasma, or gas etchant) one or more layers from a wafer or substrate. A portion of the substrate may be protected from etching by the use of an “etch mask,” which may comprise material that resists etching. Etch mask materials may include, for example, silicon nitride, silicon dioxide, aluminum, titanium, nickel or gold. Etching may include wet etching (e.g., using chemical etchants). Etching may include dry etching (e.g., using plasma or gas etchants), also known as plasma etching. Plasma etching may, for example, include microwave plasma etching, hydrogen plasma etching, reactive-ion etching (RIE), ion-assisted chemical vapor etching, inductively coupled plasma (ICP), transformer-coupled plasma (TCP) or capacitively coupled plasma (CCP). A plasma etcher, or etching tool, may be used to plasma etch a substrate. An etching tool may produce a plasma source (e.g., etching species) from a gas (e.g., O₂, fluorine-bearing gas) and an electric field (e.g., RF, microwave, DC). An etching species may comprise positively charged or negatively charged ions. Etching quality may be influenced in part by parameters including selectivity, uniformity, directionality, plasma density and etching rate. Plasma density may be determined by plasma process parameters such as plasma etch power, process pressure and gas flow rate.

Plasma etching may include the use of a single power source or multiple power sources. For example, a plasma etching process may include the use of a first power source (e.g., plasma power source) to generate a plasma source or etching species and a second power source to apply to a wafer or substrate. The second power source (e.g., bias power source) may, for example, be used to generate a charge (e.g., bias) on a surface of the substrate to modify a reaction between the etching species a material of the substrate. For example, a second power source may be used to generate a positive charge on the substrate which may accelerate etching through a reaction with a negatively charged etching species. An amount of power used for the first power source may be a “plasma power” and an amount of power used for the second power source may be a “bias power.”

The term “plasma power,” as used herein, may generally refer to an amount of power provided by a power source (e.g., plasma power source) to generate plasma. An excitation frequency, such as a radiofrequency (RF) excitation may be applied to a plasma power source to generate plasma at a certain frequency (e.g., 13.56 MHz, 2.45 GHz). Excitation frequency may affect plasma discharge characteristics and etching characteristics, in part, by affecting a spatial distribution of plasma species, electric field across plasma discharge and electron energy distribution. Uniformity of etching may be characterized in part by an evenness of etching across a substrate and a degree of etching rates maintained through the process of etching a substrate, or multiple substrates in a reactor. A power source used for a plasma etching process may vary according to, and may be limited by, the plasma etching tool used. A power source may also vary according to tool geometry and power handling capability. In some examples, a power source may be less than or equal to about 25 W. In some examples, a power source may be at least about 25 W, at least about 100 W, at least about 500 W, at least about 1000 W, at least about 3,000 W, at least about 5,000 W or greater. Plasma etch power may be within a range from about 25 W to about 100 W, from about 100 W to about 300 W, from about 300 W to about 600 W, from about 600 W to about 1,000 W, from about 3,000 W to about 5,000 or greater.

The term “etch angle” or “average etch angle,” as used herein, generally refers to an angle between a first surface, which may comprise an unetched area, and a second surface comprising an etched area. For example, an etch angle may be defined by an angle between a surface of a substrate and a surface of a feature or a surface of a hollow region of the substrate. An etch angle may be defined by an angle between a surface of the substrate and a surface of an etched area of the substrate.

In some examples, an etch angle may be defined as an angle between a surface of a substrate comprising a semiconductor material and a surface of an etched feature comprising a semiconductor material.

In some examples, an etch angle may be defined as an angle between a surface of a diamond substrate and a surface of an etched feature of the diamond substrate.

In some examples, an etch angle may be defined as an angle between a surface of a diamond substrate and a surface of an etched feature of the diamond substrate, wherein the etched feature comprises a semiconductor material.

An etch angle may, for example, be less than about 80 degrees. An etch angle may be less than or equal to about 80 degrees. An etch angle may be at least about 80 degrees, at least about 84 degrees, at least about 86 degrees, at least about 88 degrees or greater. An etch angle may, for example, be within a range from about 80 degrees to about 84 degrees, from about 84 degrees to about 86 degrees, from about 86 degrees to about 88 degrees, from about 88 degrees to about 90 degrees or from about 86 degrees to about 90 degrees.

An etching process may be characterized by parameters including, for example, etch rate, etch time, etch selectivity and etch power (e.g., plasma power). An etch rate, for example, may be less than or equal to about 0.4 microns per minute (um/min) (e.g., less than or equal to about 0.01 um/min). An etch rate may be at least about 0.01 um/min, at least about 0.05 um/min, at least about 0.4 um/min, at least about 0.5 um/min, at least about 1 um/min or at least about 1.5 um/min or greater, for example. An etch rate may, for example, be within a range from about 0.01 um/min to about 0.25 um/min, from about 0.25 um/min to about 0.4 um/min, from about 0.4 um/min to about 0.5 um/min, from about 0.4 um/min to about 1 um/min, from about 0.5 um/min to about 1 um/min, from about 1 um/min to about 1.5 um/min or from about 0.5 um/min to about 1.5 um/min, or greater. An etch time may, for example, may be less than or equal to about 1 hour. An etch time may be about 2 hours, about 4 hours, about 10 hours or greater. An etch time may be at least about 2 hours, at least about 4 hours, at least about 10 hours or greater. An etch time may be within a range from about 2 hours to about 4 hours, from about 4 hours to about 8 hours, from about 8 hours to about 10 hours, from about 10 hours to about 20 hours or from about 20 hours to about 50 hours.

The term “etch selectivity ratio,” “etch selectivity,” or “selectivity” (or variations thereof), as used herein, may generally refer to a ratio between an etch rate of a first material and an etch rate of a second material. For example, an etch selectivity ratio may be defined as a ratio between an etch rate of a substrate material and an etch rate of an etch mask material, or vice versa. An etch selectivity ratio may also be defined as a ratio between a rate of etching of a first portion of a substrate and a rate of etching of a second portion of a substrate. An etch selectivity ratio may be less than or equal to about 4:1. A selectivity may be at least about 4:1, at least about 6:1, at least about 20:1, at least about 25:1, at least about 50:1 or greater. A selectivity may be in a range from about 6:1 to about 20:1, from about 20:1 to about 25:1, from about 25:1 to about 50:1, from about 10:1 to about 50:1, or greater.

The term “intermediate layer,” as used herein, generally refers to a material layer disposed between two material layers, for example, between two layers of materials having similar or varying properties. Intermediate layers may comprise single crystalline, polycrystalline or amorphous materials. Intermediate layers may comprise wide-bandgap semiconductors, as described herein. Intermediate layers may comprise carbon-containing materials as described herein. Individual layers surrounding an intermediate layer may comprise materials having different lattice-constants or different lattice structures. Individual layers surrounding an intermediate layer may comprise materials having different thermal conductivities and/or different sheet resistivities. An intermediate layer may comprise an interface or interface layer between two material layers. An intermediate layer may have a thickness from about sub-nanometer to tens of microns. An intermediate layer may have a thickness from about 20 nm to about 2,000 nm. An intermediate layer may have a thickness between about 1 nm and 50 nm, between 10 nm and 100 nm, etc. An intermediate layer may have a thickness greater than about 1 nm, 2 nm, 5 nm, greater than 10 nm, 20 nm, greater than 50 nm, greater than 100 nm, greater than 1 micron or greater. An intermediate layer may have a thickness less than about 1 micron, less than 100 nm, less than 50 nm, less than 20 nm, less than 10 nm, less than 5 nm, less than 2 nm, less than 1 nm, or less. An intermediate layer may have a thickness from about 1 nm to about 150 nm, about 150 nm or greater than 150 nm. An intermediate layer may be thinned by a method such as mechanical polishing or etching.

An intermediate layer may comprise an anchoring layer. An intermediate layer may comprise an immobilizing layer. An intermediate layer may comprise a tacking layer. An anchoring layer may assist in anchoring diamond seeds to a material layer, for example, anchoring a layer of diamond seeds to a semiconductor-containing material layer.

An immobilizing layer may assist in immobilizing a layer of diamond seeds over a surface of a semiconductor-containing material layer. A tacking layer may assist in tacking a layer of diamond seeds to a surface of a semiconductor-containing material layer. In some examples, the diamond seeds may be immobilized, anchored or tacked to a semiconductor surface, in part, through Van der Waals bonding between the diamond seeds and the semiconductor surface. In some examples, the diamond seeds may be immobilized, anchored or tacked to a semiconductor surface, in part, through adhesion of the intermediate layer to the semiconductor surface.

An intermediate layer may comprise a transition layer between two material layers or two substrates. In some examples, a transition layer may bridge a first lattice structure (e.g., first lattice constant) of a first material layer to a second lattice structure (e.g., second lattice constant) of a second material layer, for example, within a layered semiconductor structure. One or more transition layers may be used to accommodate for a change in the lattice constants and help absorb dislocations between two material layers or substrates.

An intermediate layer may comprise a nucleation layer. The term “nucleation layer” or “nucleating layer,” as used herein, generally refers to a material layer that assists in starting the growth or formation of another layer of material or stoichiometry. Nucleating layer materials can include semiconductors, for example, wide-bandgap semiconductors. Nucleating materials can include silicon, silicon nitride (SiN), silicon carbide (SiC) or other materials that may aid in the nucleation of synthetic diamond. Nucleating materials can include, for example, InGaN, InAlN, AlN, ScAlN or derivatives thereof. Nucleating layer materials can assist in preventing etching or damage to an underlying semiconductor material or substrate. Nucleating materials can be amorphous or polycrystalline. The presence of a nucleating layer may create multiple interfaces between a layered semiconductor structure and a substrate. Multiple interfaces can include, for example, (i) a first interface between a diamond substrate and a nucleating layer and (ii) a second interface between the nucleating layer and a layered semiconductor structure.

Nucleating layer(s) may be disposed between two material layers or substrates, such as two material layers having similar or varying properties. A nucleating layer may have similar properties to a material to which the nucleating layer assists in the growth of. Nucleating layers may be used in nucleating diamond on semiconductor-containing structures. Nucleating layers may be protective layers that protect such structures from damage. Such structures may include one or more nucleating layers disposed between a semiconductor-containing material and diamond. A nucleating layer may be an individual layer that is independent from a semiconductor-containing structure and may be disposed on a surface of such structure. In some cases, a nucleating layer may be nucleation material that is added to a final stage of growth of such structure (e.g., final stage of epitaxial growth), in which case the nucleation material may not be an independent layer but may be integrated into the structure near a surface (e.g., top surface). A diamond growth process can include a nucleation phase in which a nucleating layer and a set of diamond-growth conditions can enhance diamond nucleation on a host substrate. Diamond-growth conditions can include conditions within a vacuum chamber, for example, in the case of vapor deposition (e.g., CVD).

Heat removal systems for devices such as power amplifiers may be large in comparison with a heat source and may limit performance. Diamond heat-sinks, heat-spreaders, and other diamond plates may be useful in spreading heat below a semiconductor device for thermal management. A diamond heat-sink may be a thermal component to which a device can be attached, wherein the diamond heat-sink assists in spreading heat generated by the device. In some cases, diamond substrates may differ from diamond heat-sinks, heat-spreaders or plates. For example, a diamond substrate may comprise a substrate on which active electronic device layers are disposed to form a device (e.g., die, chip).

Depositing diamond seeds onto substrate materials may include ultrasonic seeding, a process that can include placing a substrate in an ultrasonic seeding solution or bath (e.g., containing diamond particles) and agitating the bath until the diamond particles adhere to the substrate.

Some alternatives to bonding and die-attachment may include selective area deposition (SAD) and the use of nucleating layers or nucleating materials for nucleating diamond on semiconductor materials. Some alternatives may include the use of selective area nucleation.

SAD can include using photoresist (or other materials) as sacrificial layers to seed and grow diamond over a semiconductor structure. SAD may also include applying nucleation layers between photoresist coatings to define areas for diamond growth on a substrate. In some cases, during ultrasonic seeding, diamond particles may adhere to the photoresist (or a nucleating material) instead of a surface of a semiconductor structure and diamond may be grown over the semiconductor structure from the seeded diamond particles in the photoresist or other material.

The term “substrate feature” or “feature,” as used herein, may generally refer to a shortest average distance between two manufactured raised edges or lower edges in a substrate. In some cases, a substrate feature may be a hollow region in a substrate. In some cases, a substrate feature may be a raised region in a substrate. A feature size may generally relate to a resolution of a manufacturing process. For example, a manufacturing process with a higher resolution may be able to create features with a smaller feature size. In some cases, a “substrate feature” may be a vertical interconnection access (“via”), channel, singulation trench, die street or street in a substrate, for example. A “via” or “through-substrate via” (or variations thereof) as used herein, may generally refer to an electrical connection disposed between layers in a substrate, such as a layered semiconductor-containing structure or a wafer. A via may couple a first layer of the substrate to a second layer of the substrate, a first device or circuit to second device or circuit, or to an antenna, or other component, for example. A via may couple a top or front side of a substrate to a bottom or back side of the substrate. A via may couple a via pad on a first side of the substrate to a metal layer on a second side of the substrate, for example, to provide electrical ground to a device disposed on or within the substrate or a layered structure.

A feature may comprise a hollow region within a substrate. A hollow region in a substrate, for example, may be generated at least in part by etching a portion of a semiconductor structure, for example, a layered structure. A hollow region may be generated at least in part by etching a portion of a structure that comprises substrate material. Etching substrate material may result in removal of the material. The hollow region may continue through more than one layer of the substrate, including more than one material.

A feature may also comprise a hollow region in a substrate, including one or more substrate layers, that may be plated with an electrically conductive material, such as a metal. Such feature may communicatively couple two or more layers of the substrate. A plating within a feature may have a thickness of less than or equal to about 4 microns, at least 1 micron, at least 4 microns, at least 5 microns, at least 6 microns, at least 12 microns, at least 15 microns, or greater. A plating within a feature may have a thickness within a range from about 1 micron to about 4 microns, from about 4 microns to about 6 microns, from about 6 microns to about 12 microns, from about 12 microns to about 15 microns, or greater.

A feature may comprise a portion of a semiconductor structure. A semiconductor structure may, for example, be a layered structure or a wafer. A feature may comprise, for example, a singulation feature (e.g., singulation trench or a die street). A feature may comprise an edge of a semiconductor structure, such as an edge of a die after dicing of a wafer. At least a portion of a feature may be cut away from the wafer during a dicing process. In some examples, after a feature is cut away, an edge of a die may be left with at least a portion of the feature. For example, an edge of a die may be left with at least a portion the feature comprising a material. A feature may comprise a semiconductor material. A feature may comprise silicon. A feature may comprise a material having an average value of thermal conductivity equal to or greater than about 1,000 W/mK. A feature may comprise a material having a plurality of crystals (e.g., crystal grains). Each of the plurality of crystal grains may have an average crystal grain diameter from about 10 nm to about 2,000 nm. In some examples, at least a portion of the plurality of crystal grains is disposed a distance of less than or equal to about 100 microns from a surface of a feature. At least a portion of the plurality of crystal grains may be disposed a distance of less than or equal to about 60 microns, less than or equal to about 25 microns, less than or equal to about 10 microns, less than or equal to about 5 microns, less than or equal to about 1,000 nm, less than or equal to about 100 nm, less than or equal to about 50 nm, less than or equal to about 25 nm or less, from a surface of a feature. A feature surface may, for example, be a surface or edge of the die after dicing a wafer. A feature surface may be a surface of a die street (e.g., before dicing of a wafer). A feature surface may be a surface of a via hole or hollow region. A feature surface may be a surface of a semiconductor material.

A feature may comprise an average feature size. An average feature size may be characterized by parameters including an average height, and average width or average diameter, an average aspect ratio and an average etch angle. A feature may be round or rectangular shaped. A feature height may be defined by a substrate thickness or layer thickness of a layer in the substrate. A feature may have a width or diameter of at least about 1 micron, at least about 10 microns, at least about 20 microns, at least about 30 microns, at least about 40 microns, at least about 50 microns, at least about 60 microns or greater. A feature may have a width or diameter of less than or equal to about 20 microns. A feature may have a width or diameter of less than or equal to about 40 microns. A feature may have a width or diameter within a range from about 1 micron to about 100 microns, within a range from about 10 microns to about 100 microns, within a range from about 20 microns to about 100 microns, within a range from about 30 microns to about 100 microns or within a range from about 40 microns to about 100 microns, within a range from about 60 microns to about 100 microns or greater. A feature may have a width or diameter within a range from about 10 microns to about 40 microns, within a range from about 10 microns to about 60 microns or greater. A feature may have a height varying from sub-nanometer to hundreds of microns. A feature may have a height less than or equal to about 600 microns. A feature may have a height less than or equal to about 150 microns. A feature may have a height of at least about 1 micron, at least about 25 microns, at least about 50 microns, at least about 100 microns or greater.

A feature may be characterized by an “aspect ratio” or “average aspect ratio.” In some examples, an aspect ratio (e.g., an average aspect ratio) may generally refer to a ratio between a height of a feature and a width or diameter of the feature (e.g., height-to-width aspect ratio). For example, a feature having a height of 100 microns and a diameter or width of 20 microns may have an aspect ratio of 5:1, 5/1 or 5. As another example, a feature having a height of 50 microns and a width of 40 microns may have an aspect ratio of 1.25:1 or 1.25. A feature may have an aspect ratio of at least about 0.25:1. A feature may have an aspect ratio of at least about 1:1, at least about 1.25:1, at least about 2:1, at least about 3:1, at least about 4:1, at least about 5:1, at least about 7:1, at least about 10:1 or greater.

In some examples, an aspect ratio may generally refer to a ratio between a first width or diameter of a feature and a second width or diameter of the feature (e.g., width-to-width aspect ratio). For example, an aspect ratio may refer to a ratio between a width or diameter of a feature on a first surface of a substrate and a width or diameter of the feature on a second surface of the substrate. In some examples, a feature may comprise a first width or diameter on a backside surface of a substrate and a second width or diameter on a frontside surface of the substrate. The backside surface, the frontside surface, or both, may comprise a material having an average thermal conductivity equal to or greater than about 1,000 W/mK. The backside surface, the frontside surface, or both, may comprise diamond. The frontside surface may comprise an interface between diamond and another material different from diamond. The frontside surface may comprise another material different from diamond, for example, a semiconductor containing material.

A substrate may comprise one or more features that may be disposed proximate to a device or component of the substrate, such as a transistor. In some examples, such components may be disposed on a surface of the substrate. Components may also be disposed within a substrate, such as within epitaxial layers of a substrate. In some examples, a distance between a feature and a component may be defined by a distance between a surface or edge of the component and a surface of the feature (e.g., inner surface). A distance between a feature and a component may be, for example, less than or equal to about 200 micrometers (or microns, um, p), less than or equal to about 100 microns, less than or equal to about 75 microns, less than or equal to about 60 microns, less than or equal to about 50 microns, less than or equal to about 30 microns, less than or equal to about 20 microns, less than or equal to about 15 microns, or less. A distance between a feature and a component may be within a range from about 30 microns to about 20 microns, from about 20 microns to about 10 microns, from about 10 microns to about 5 microns, or less.

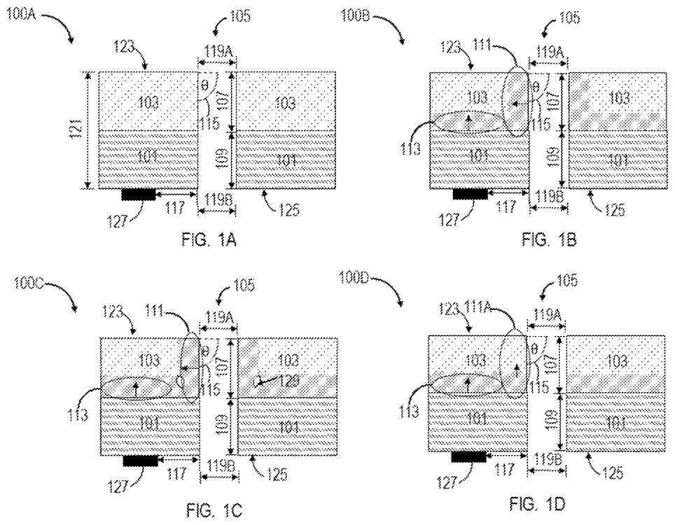

Elements shown in FIG. 1-FIG. 5 are not to scale and may include, for example, magnified or exaggerated thicknesses and surface roughness.

FIG. 1A illustrates a cross-sectional view of an example substrate 100A, in accordance with some embodiments disclosed herein. The substrate 100A may be a compound semiconductor-containing substrate.

FIG. 1B illustrates a cross-sectional view of an example substrate 100B, in accordance with some embodiments disclosed herein. The substrate 100B may be a compound semiconductor-containing substrate. The substrate 100B may comprise one or more elements that are similar to elements of substrate 100A.

FIG. 1C illustrates a cross-sectional view of an example substrate 100C, in accordance with some embodiments disclosed herein. The substrate 100C may be a compound semiconductor-containing substrate. The substrate 100C may comprise one or more elements that are similar to elements of substrate 100B.

FIG. 1D illustrates a cross-sectional view of an example substrate 100D, in accordance with some embodiments disclosed herein. The substrate 100D may be a compound semiconductor-containing substrate. The substrate 100D may comprise one or more elements that are similar to elements of substrates 100A-100C.

Referring to FIG. 1A, the substrate 100A may include a semiconductor-containing structure 101 such as a layered structure, a layer of carbon-containing material 103 and a feature 105. The substrate 100A may include a component 127. The material 103 may have an average value of thermal conductivity equal to or greater than about 1,000 W/mK. The material 103 may comprise diamond. The structure 101 may include one or more wide-bandgap semiconductor materials. The structure 101 may include, for example, a material selected from the group consisting of GaN, AlN, InGaN, MAIN, AlGaN, InGaAlN, Ga2O3, ScAlN, and derivatives and combinations thereof.

The substrate 100A comprises a feature 105, which may be a feature as described herein, for example, an interconnect (e.g., via), channel or die street. The feature 105 may comprise a height (e.g., 107, 109 or both) and a width (or diameter) (e.g., 119A or 119B). A feature height may be similar to a substrate height 121 or may be a fraction of a substrate height (e.g., less than substrate height 121). The feature 105 may comprise a height 107, which may be a height of the feature 105 within the material 103. The feature 105 may comprise a height (e.g., 107 and 109) such that the structure 101 and the material 103 both comprise at least a portion of the feature 105. The height 107 may be from about 20 microns to about 600 microns. The height 109 may be from about 0.1 microns to about 5 microns.

The feature 105 may comprise sidewalls. The width of the feature 105 may vary according to a location of measurement within the substrate, for example, feature 105 may comprise a first width 119A at a location proximate to a first surface 123 of the substrate 100A and a second width 119B at a location proximate to a second surface 125 of the substrate 100A. Other widths of the feature 105 may be within a range from width 119A to 119B depending on a location of measurement, for example, depending on a depth within the substrate 100A relative to a surface (e.g., 123, 125) of the substrate 100A. For example, the feature 105 may have a width of at least about 1 micron, at least about 10 microns, at least about 20 microns, at least about 30 microns, at least about 40 microns, at least about 50 microns, at least about 60 microns or greater. A feature may have a width of less than or equal to about 20 microns. A feature may have a width of less than or equal to about 40 microns. The feature 105 may be characterized in part by an aspect ratio. The aspect ratio of feature 105 may be defined by a ratio of the height of the feature 105 to the width or diameter of the feature 105. The aspect ratio may be greater than about 1.25:1. The aspect ratio may be within a range from about 1.25:1 to about 5:1, or greater. The aspect ratio may be within a range from about 1.25:1 to about 11:1. An aspect ratio of feature 105 may be defined by a ratio of a first width or diameter to a second width or diameter.

The feature 105 may comprise a hollow region within the substrate 100A. The feature 105 may comprise a hollow region with sidewalls. The sidewalls may be plated with an electrically conductive material. The thickness of the plating may be within a range from about 1 micron to about 4 microns, for example. The feature 105 may comprise an etch angle 115. Etch angle 115 may comprise an angle measured from a surface (e.g., sidewall) of the feature 105 to the horizontal (e.g., horizontal plane located proximate to surface 123 of the substrate 100A). The etch angle 115 may be greater than or equal to about 80 degrees. The etch angle 115 may be within a range from about 86 degrees to about 90 degrees, for example. The etch angle may be greater than 90 degrees.

The structure 101 may be formed on a separate growth substrate (not shown). The structure 101 may include one or more layers. At least a portion of one or more layers of the substrate 100A may be removed (e.g., by etching or mechanical polishing). Material 103 may comprise a high-thermal conductivity material. Material 103 may have an average thermal conductivity of at least about 1,000 W/mK in at least a single dimension (e.g., vertical dimension, horizontal dimension). The thermal conductivity may be greater than at least about 50 W/mK, 100 W/mK, 500 W/mK, 1,000 W/mK, 2,000 W/mK, 3,000 W/mK, or more. The thermal conductivity may be within a range from about 500 W/mK to about 2,000 W/mK. The thermal conductivity may be within a range from about 500 W/mK to about 3,000 W/mK. The thermal conductivity may be within a range from about 1,500 W/mK to about 2,500 W/mK.

The structure 101 may include a buffer layer. The structure 101 may include a barrier layer. The structure 101 may include a 2DEG layer. The structure 101 may include one or more transition layers.

Material 103 may comprise at least one layer of diamond (e.g., synthetic diamond). Material 103 may comprise chemical vapor deposited diamond. Material 103 may comprise a thickness of at least 1 micron of diamond. Material 103 may comprise a thickness of diamond of at least about 1 micron, at least about 10 microns, at least about 50 microns, at least about 100 microns, at least 1 about millimeter or more. Material 103 may comprise a thickness of at least 1 millimeter of diamond. Material 103 may comprise a thickness of diamond within a range from about 1 micron to about 1 millimeter, within a range from about 10 microns to about 1 millimeter, within a range from about 50 microns to about 1 millimeter or within a range from about 100 microns to about 500 microns.

The substrate 100A may include one or more intermediate layers. One or more intermediate layers may be disposed between the structure 101 and the material 103. The substrate 100A may include at least one interface between structure 101 and material 103. The interface may be a single interface.

A component 127 may be disposed on a surface of the substrate 100A. The component 127 may be disposed a distance 117 from a surface of the feature 105. The distance 117 may be less than or equal to about 100 microns from a surface of the feature 105.

Referring to substrate 100B in FIG. 1B, the material 103 may comprise a region 111. The region 111 may comprise a plurality of crystals, for example, a plurality of diamond crystals. The plurality of crystals may each have an average crystal grain size (e.g., diameter). The average crystal grain size may be a diameter from about 5 nm to about 2,000 nm. The diameter may be from about 5 nm to about 100 nm. The diameter may be less than about 150 nm, less than about 100 nm, less than about 75 nm, less than about 50 nm, less than about 25 nm, less than about 10 nm, less than 5 nm, or less. At least a portion of the region 111 may be disposed a distance of less than or equal to about 100 microns (e.g., less than about 60 microns) from a surface of the feature 105. At least a portion of the region 111 may be disposed a distance of less than about 100 microns, less than about 75 microns, less than about 50 microns, less than about 25 microns, or less, from a surface of the feature 105. At least a portion of the region 111 may be disposed proximate to a surface of the feature 105. At least a portion of the region 111 may be disposed adjacent to a surface of the feature 105. The region 111 may be disposed a distance of less than or equal to about 100 microns (e.g., less than about 60 microns) from an edge of the substrate 100B, for example, after singulation of substrate 100B if feature 105 is a die street of substrate 100B.

The material 103 may comprise a region 113. The region 113 may comprise a plurality of crystals, for example, a plurality of diamond crystals. The plurality of crystals may each have an average crystal grain diameter. An average crystal grain diameter of the plurality of crystals in region 113 may be from about 5 nm to about 2,000 nm. The diameter may be from about 5 nm to about 100 nm. A crystal grain diameter may be less than about 150 nm, less than about 100 nm, less than about 75 nm, less than about 50 nm, less than about 25 nm, less than about 10 nm, less than about 5 nm or less. At least a portion of the region 113 may be disposed a distance of less than about 50 microns from an interface between the material 103 and the structure 101. At least a portion of the region 113 may be disposed adjacent to the interface between the material 103 and the structure 101.

The average crystal grain size (e.g., diameter) of the region 111 may increase in a direction away from a surface of the feature 105, represented by the arrow in region 111. The average crystal grain density of the region 111 may change (e.g., decrease) in a direction away from a surface of the feature 105, represented by the arrow in region 111. The average crystal grain size (e.g., diameter) of the region 113 may increase in a direction away from an interface between the material 103 and the structure 101, represented by the arrow in region 113. The average crystal grain density of the region 113 may change (e.g., decrease) in a direction away from the interface between the material 103 and the structure 101, represented by the arrow in region 113.

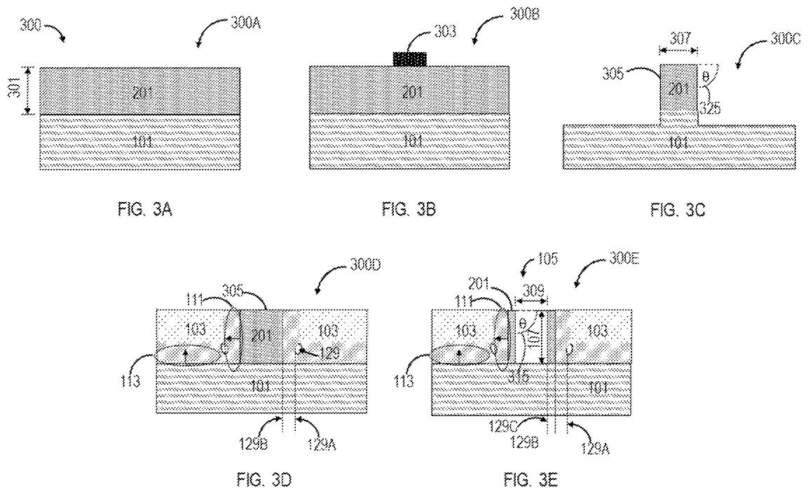

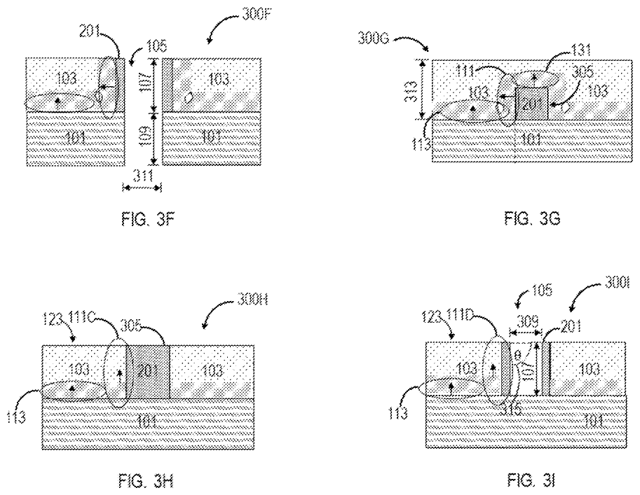

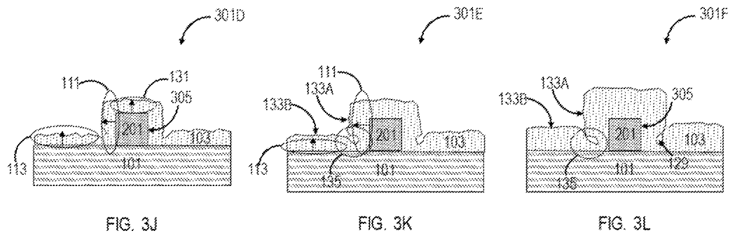

The average crystal grain size of the region 111 may increase generally proportional to a distance away from a surface of the feature 105, represented by the arrow in region 111. The average crystal grain size of the region 113 may increase generally proportional to a distance away from the interface between the material 103 and the structure 101, represented by the arrow in region 113. FIG. 3A and FIG. 3B provide additional details on the growth of material 103.

Referring to substrate 100C in FIG. 1C, the material 103 may comprise a keyhole (e.g., void or air pocket) 129. The keyhole 129 may comprise an area where substantially no crystal grains exist in the material 103. The keyhole 129 may comprise a gap between a portion of the plurality of crystal grains of the region 111 and a portion of the plurality of crystal grains of the region 113. The keyhole 129 may be formed at least in part from a difference in an average diameter of the crystal grains in region 111 to the crystal grains in region 113. The keyhole 129 may be disposed a distance of less than or equal to about 100 microns (e.g., less than about 60 microns) from a surface of the feature 105. The keyhole 129 may be disposed a distance of less than or equal to about 100 microns (e.g., less than about 60 microns) from an edge of the substrate 100C, for example, after singulation of substrate 100C if feature 105 is a die street of substrate 100C. FIG. 3A and FIG. 3B provide additional details on the formation of the keyhole 129.

Referring to FIG. 1D, region 111A may vary from region 111 in FIG. 100B in that an average crystal grain size (e.g., diameter) of the region 111A may not increase in a direction away from a surface of the feature 105. Instead, the crystal grain size may increase in a direction away from the interface between the material 103 and the structure 101. The crystal grain size may increase in a direction substantially parallel to a surface of the feature 105, represented by the arrow in region 111A. The average crystal grain size of the region 111A may increase generally proportional to a distance away from the interface between the material 103 and the structure 101 and substantially parallel to a surface of the feature 105.

In some examples, the material 103 may begin growth at a location proximate to the interface between the material 103 and the structure 101 (e.g., begin growth from a surface of the material 101) and the crystal grains may end growth at a location proximate or adjacent to surface of the feature 105 (e.g., ending growth at the surface of feature 105). The crystal grains of the material 103 may form a surface adjacent to the feature 105 that has a threshold surface roughness (e.g., root mean squared surface roughness). The surface roughness may be from about 20 nanometers to about 10 microns, for example. The surface roughness may be less than 50 microns, less than 30 microns, less than 20 microns, less than 5,000 nanometers, less than 1,000 nanometers, less than 500 nanometers, less than 100 nanometers, less than 50 nanometers, or less than 20 nanometers or less. The material 103 may form a surface adjacent to the feature 105 that comprises a plurality of voids (e.g., holes, air pockets) and the voids at an interface between the material 103 and the feature 105 may have diameters that are proportional to the size of the crystal grain sizes.

In some examples, etching of a material (e.g., material of a feature mold 305) to expose the feature 105 may also expose a surface of the material 103. The surface of the material 103 may have a threshold surface roughness that is formed in part by the crystal grains during growth of the material 103. In some examples, a surface roughness may be proportional to a size of the crystal grains (e.g., diameter). The surface roughness may increase or decrease in a direction parallel to the surface of the feature 105, in a direction toward or away from the interface between the material 103 and the structure 101. The surface roughness may increase in a direction away from the interface between the material 103 and the structure 101.

In some examples, a surface of the feature formed by the growth of the material 103 is different from a surface of the feature that may be formed by etching or drilling of the feature. For example, a surface of the feature formed by growth of the material 103 may have a higher surface roughness compared to etching or drilling away the material 103 to form the feature.

In some examples, the feature surface formed by the growth of the material 103 may be different from a surface generated by etching, wherein a surface roughness may be determined by a roughness generated by an etching process or by a mask pattern, and not by a crystal grain size.

The feature 105 may be plated following an etching of a feature mold to expose the feature 105 and the surface of the material 103 having a threshold surface roughness. In some examples, plating the surface of the material 103 (e.g., inside the feature 105) may form a plated surface that has a surface roughness proportional to the surface roughness of the material 103.

In some embodiments, the diamond substrate material 103 may be generated by selective area growth. In such embodiments, diamond seeds may be deposited over at least a portion of a surface of the structure 101. For example, the diamond seeds may be deposited around the feature 105.

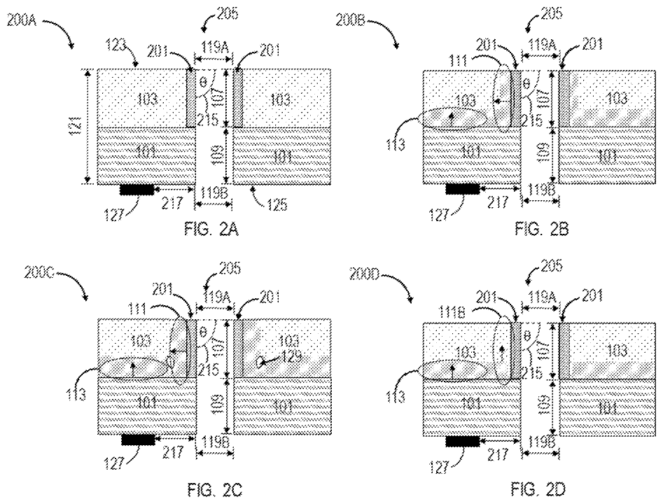

FIG. 2A illustrates a cross-sectional view of an example substrate 200A, in accordance with some embodiments disclosed herein. The substrate 200A may be a compound semiconductor-containing substrate. The substrate 200A may comprise one or more elements that are similar to elements of substrate 100A.

FIG. 2B illustrates a cross-sectional view of an example substrate 200B, in accordance with some embodiments disclosed herein. The substrate 200B may be a compound semiconductor-containing substrate. The substrate 200B comprises one or more elements that are similar to elements of substrate 200A and substrate 100B.

FIG. 2C illustrates a cross-sectional view of an example substrate 200C, in accordance with some embodiments disclosed herein. The substrate 200C may be a compound semiconductor-containing substrate. The substrate 200C comprises one or more elements that are similar to elements of substrate 200B and substrate 100C.

FIG. 2D illustrates a cross-sectional view of an example substrate 200D, in accordance with some embodiments disclosed herein. The substrate 200D may be a compound semiconductor-containing substrate. The substrate 200D may comprise one or more elements that are similar to elements of substrates 200B and 100D.

Referring to FIG. 2A, the substrate 200A may include a semiconductor-containing structure 101 such as a layered structure, a layer of carbon-containing material 103 and a feature 205. The substrate 200A may include a component 127. The material 103 may have an average value of thermal conductivity equal to or greater than about 1,000 W/mK. The material 103 may comprise diamond. The structure 101 may include one or more wide-bandgap semiconductor materials. The structure 101 may include, for example, a material selected from the group consisting of GaN, AlN, InGaN, InAlN, AlGaN, InGaAlN, Ga2O3, ScAlN, and derivatives and combinations thereof.

The substrate 200A may comprise material 201, which may be a semiconductor material. The material 201 may comprise silicon, for example, SiN. The material 201 may comprise at least a portion of a feature mold, for example, a feature mold similar to the feature mold described in FIG. 3 through FIG. 5.

The material 201 may have a height similar to the height of material 103 (e.g., 107). The material 201 may have a width from about 1 micron to about 1,000 microns.

The substrate 200A comprises a feature 205, which may be an interconnect (e.g., via), channel or die street. The feature 205 may comprise a height (e.g., 107, 109 or both) and a width (or diameter) (e.g., 119A or 119B). A feature height may be similar to a substrate height 121 or may be a fraction of a substrate height (e.g., less than substrate height 121). The feature 205 may comprise an etch angle 215. The feature 205 may comprise at least a portion of the material 201. The feature 205 may comprise at least a portion of the structure 101.

Etch angle 215 may comprise an angle measured from a surface (e.g., sidewall) of the feature 205 to the horizontal (e.g., horizontal plane located proximate to surface 123 of the substrate 200A). The etch angle 215 may be greater than or equal to about 80 degrees. The etch angle 215 may be within a range from about 86 degrees to about 90 degrees, for example. The etch angle 215 may be greater than 90 degrees.

At least a portion of the material 201 may be disposed proximate to the feature 205. For example, at least a portion of the material 201 may be disposed a distance of less than or equal to about 100 microns from a surface of the feature. In some examples, at least a portion of the material may be disposed a distance of less than or equal to about 100 microns from an edge of the substrate 200A, for example, after singulation of substrate 200A if feature 205 is a die street of substrate 200A.

The structure 101 may be formed on a separate growth substrate. In some examples, the material 201 may comprise a portion of a growth substrate on which the structure 101 formed. A portion of the growth substrate may be removed prior to growth of the material 103. The structure 101 may include one or more layers. At least a portion of one or more layers of the substrate 200A may be removed (e.g., by etching or mechanical polishing).

The component 127 may be disposed on a surface of the substrate 200A. The component 127 may be disposed a distance 217 from a surface of the feature 205. The distance 217 may be less than or equal to about 100 microns from a surface of the feature 205.

Referring to FIG. 2B, the material 103 may comprise a region 111B and a region 113. The region 111B and the region 113 may each comprise a plurality of crystals, for example, a plurality of diamond crystals. The region 111B and the region 113 may have elements similar to the elements of region 111 and region 113, respectively, in FIG. 1A to FIG. 1C. The plurality of crystals may each have an average crystal grain size, for example, a diameter from about 5 nm to about 100 nm. At least a portion of the region 111B may be disposed a distance of less than or equal to about 100 microns (e.g., less than about 60 microns) from a surface of the feature 205. At least a portion of the region 111B may be disposed a distance of less than or equal to about 100 microns (e.g., less than about 60 microns) from a surface of the material 201, for example at an interface between the material 201 and the material 103. The average crystal grain size of the region 111B may increase in a direction away from a surface of the feature 205, represented by the arrow in region 111B. The average crystal grain size of the region 113 may increase in a direction away from a surface of an interface between the material 103 and the structure 101, represented by the arrow in region 113.

Referring to FIG. 2C, the material 103 may comprise a keyhole (e.g., void or air pocket) 129. The keyhole 129 may have elements similar to the elements of the keyhole 129 in FIG. 1C. The keyhole 129 may comprise an area where substantially no crystal grains exist in the material 103. The keyhole 129 may comprise a gap between a portion of the plurality of crystal grains of the region 111 and a portion of the plurality of crystal grains of the region 113. The keyhole 129 may be formed at least in part from a difference in an average diameter of the crystal grains in region 111 to the crystal grains in region 113. The keyhole 129 may be disposed a distance of less than or equal to about 100 microns (e.g., less than about 60 microns) from a surface of the feature 205 or a surface of the material 201. FIG. 3A and FIG. 3B provide additional details on the formation of the keyhole 129.

The example methods described with respect to FIG. 3A through FIG. 6 may include additional or even fewer operations or processes in comparison to what is illustrated in any of FIG. 3A through FIG. 6. Additionally, examples of the methods described with respect to FIG. 3A through FIG. 6 are not necessarily limited to the chronological order that is shown in such figures.

Referring to FIG. 2D, region 111B may vary from region 111 in FIG. 100B in that an average crystal grain size (e.g., diameter) of the region 111B may not increase in a direction away from a surface of the feature 105. Instead, the crystal grain size may increase in a direction away from the interface between the material 103 and the structure 101. The crystal grain size may increase in a direction substantially parallel to a surface of the feature 105, represented by the arrow in region 111B. The average crystal grain size of the region 111B may increase generally proportional to a distance away from the interface between the material 103 and the structure 101 and substantially parallel to a surface of the feature 105.

In some examples, the material 103 may begin growth at a location proximate to the interface between the material 103 and the structure 101 (e.g., begin growth from a surface of the material 101) and the crystal grains may end growth at a location proximate or adjacent to surface of the feature 105 (e.g., ending growth at the surface of feature 105). The crystal grains of the material 103 may form a surface adjacent to the feature 105 that has a threshold surface roughness (e.g., root mean squared surface roughness). The surface roughness may be from about 20 nanometers to about 10 microns, for example. The surface roughness may be less than 50 microns, less than 30 microns, less than 20 microns, less than 5,000 nanometers, less than 1,000 nanometers, less than 500 nanometers, less than 100 nanometers, less than 50 nanometers, or less than 20 nanometers or less. The material 103 may form a surface adjacent to the feature 105 that comprises a plurality of voids (e.g., holes, air pockets) and the voids at an interface between the material 103 and the feature 105 may have diameters that are proportional to the size of the crystal grain sizes.

In some embodiments, the diamond substrate material 103 may be generated by selective area growth. In such embodiments, diamond seeds may be deposited over at least a portion of a surface of the structure 101. For example, the diamond seeds may be deposited around the feature 105.

FIG. 3A-FIG. 3L illustrates generally a cross-sectional view of an example method of forming a feature, in accordance with some examples.

In some cases, method 300 may include operations 300A through 300I as shown in FIG. 3A-FIG. 3I. FIG. 3J-FIG. 3L illustrates generally a cross-sectional view of an example method of forming a feature, in accordance with some examples. FIG. 3J-FIG. 3L may include operations 301D through 301F.

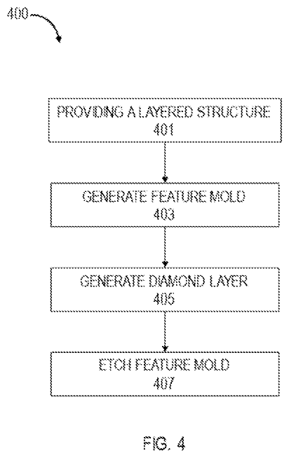

FIG. 4 illustrates generally a flow diagram of an example method 400 of generating a feature in a substrate, in accordance with some examples. In some cases, method 400 includes operations 401 through 407. In operation 401, and as illustrated, for example, by operation 300A of FIG. 3A, a substrate is provided. The substrate may comprise structure 101 and material 201. Structure 101 may be a layered semiconductor-containing structure, for example, similar to structure 101 as described with respect to FIG. TA. The material 201 may be a semiconductor material, for example, similar to material 201 as described with respect to FIG. 2A. The material 201 may comprise silicon. The material 201 may be a growth substrate upon which the structure 101 is formed. The structure 101 may include one or more transition layers. The structure 101 may include a buffer layer. The structure 101 may include a barrier layer. The structure 101 may include a 2DEG. The substrate may be disposed on a carrier wafer (not shown). The material 201 may have a height 301. The height 301 may be less than about 500 microns. The height 301 may be about 100 microns. The material 201 may be etched or ground to a height of 301.

In operation 403, and as illustrated, for example, by operation 300B of FIG. 3B, a feature mold is generated. An etch mask 303 is used to etch at least a portion of the material 201.

Operation 300C of FIG. 3C illustrates, in part, the feature mold 305 after the portion of the material 201 has been etched. A portion of the structure 101 may also be etched, for example, one or more transition layers. The feature mold 305 may have a height that is similar to the height 301 of the material 201. The feature mold 305 may be taller than the height 301 of the material 201. The feature mold 305 may have a width 307. The width 307 may be from about 5 microns to about 1,000 microns. The substrate may comprise an etch angle 325, which may be an angle measured between a horizontal plane along a surface of the material 201 and an etched surface of the feature mold 305. The etch angle 325 may be equal to or less than about 90 degrees, for example, between about 86 to about 90 degrees. The etch angle may be greater than about 90 degrees.

In operation 405, and as illustrated, for example, in operation 300D of FIG. 3D, a layer of material 103 is generated over at least a portion of the substrate. The material 103 may be a diamond substrate that is generated over at least a portion of the structure 101. The diamond substrate may be generated around the feature mold 201 in accordance with the diamond growth operations described herein (e.g., FIG. 3F-FIG. 3I). The diamond substrate may have a thickness similar to the height 301 of material 201, for example, about 100 microns.

As the diamond substrate thickness grows, for example in the directions indicated by arrows in region 111, region 113 (and, for example, region 131 relative to operation 300G of FIG. 3G), the diamond crystal sizes may increase (e.g., diameter of crystals may increase).

An average crystal grain size (e.g., diameter) of the region 111 may increase in a direction away from a surface of the feature mold 305, represented by the arrow in region 111. The average crystal grain density of the region 111 may change (e.g., decrease) in a direction away from a surface of the feature mold 305, represented by the arrow in region 111. The average crystal grain size (e.g., diameter) of the region 113 may increase in a direction away from an interface between the material 103 and the structure 101, represented by the arrow in region 113. The average crystal grain density of the region 113 may change (e.g., decrease) in a direction away from the interface between the material 103 and the structure 101, represented by the arrow in region 113.

The average crystal grain size of the region 111 may increase generally proportional to a distance away from a surface of the feature mold 305, represented by the arrow in region 111. The average crystal grain size of the region 113 may increase generally proportional to a distance away from the interface between the material 103 and the structure 101, represented by the arrow in region 113.

In some embodiments, a keyhole or void 129 may form in material 103, for example, for example, as described in more detail with respect to FIG. 3J-FIG. 3L. A location 129A of the keyhole 129 in the material 103 may be equal to or less than about 100 microns from a location 129B of a surface of the feature mold 305, as shown in FIG. 3D and FIG. 3E.

With respect to operation 300E of FIG. 3E, a location 129A of the keyhole 129 in the material 103 may be equal to or less than about 100 microns from a location 129B of a surface of the feature mold 305 or from a location 129C of a surface of the substrate feature 105.

In operation 407, and as illustrated in operation 300E of FIG. 3E, at least a portion of the feature mold 305 is etched. In some examples, all or substantially all of the feature mold 305 is etched. In some examples, an amount of the material 201 remains in the substrate after the etching of the feature mold 305. The etching of the feature mold 305 may form at least part of the feature 105. The feature 105 may comprise a hollow region of the substrate. The feature mold 305 may comprise at least a portion of the hollow region. The material 103 may comprise at least a portion of the hollow region. The feature mold 305 may be etched such that a width or thickness of the remaining material 201 on at least one side of the feature 105 is between about 1 micron to about 1,000 microns. The feature mold 305 may be etched to generate a height 107 of the feature 105. The feature mold 305 may be etched to generate a width 309 (e.g., diameter) of the feature 105. The width 309 of the feature 105, for example, may be from about 10 microns to about 60 microns. The feature mold 305 may be etched such that an etch angle 315 is generated. The etch angle 315 may be equal to or less than about 90 degrees, for example, between about 86 to about 90 degrees. The feature mold 305 may be etched such that the remaining material 201 comprises an etch angle (e.g., 315) that assists in generating a more viable feature (e.g., 105). In some cases, the method 300 concludes at an operation 300E. In some cases, one or more additional operations may be performed, such as for example, one or more operations 300F, 300G, 300H, 300I, 300J, 300K, or 300L. One or more operations of the method 300 may be repeated. One or more operations of the method 300 may be omitted.

In some examples, operation 407 further includes etching at least a portion of the structure 101, as illustrated, for example, in operation 300F of FIG. 3F, to generate an additional hollow region in the structure 101. The feature 105 may comprise the hollow region in material 103 (or in material 201) and the additional hollow region in 101. The additional hollow region in structure 101 may have a height 109 and a width 311 (e.g., diameter), which may be the same or similar to the width 309. The width 311 may be smaller than the width 309. The width 311 may be larger than the width 309.

In operation 405, and as illustrated in operation 300G of FIG. 3G, in some examples, the material 103 is generated such that a height 313 of the material 103 exceeds the height of the material 201 and the feature mold 305. For example, material may be generated with such a height in FIG. 3D that the material 103 exceeds the height of the material 201 and the feature mold 305. The material 103 may grow in a general direction from a surface of the substrate mold 305 as shown by the arrow in region 131. The average crystal grain sizes and crystal grain densities in region 131 may have elements similar to the crystal grains of region 111 and region 113. In such examples, prior to etching of the feature mold 305 in operation 300E of FIG. 3E, the height 313 of the material 103 may decreased. The height 313 of the material 103 may be decreased by lapping, grinding or etching the material 103. The resulting height of the material 103 after decreasing it may be similar to the height 301 of the material 201. In some examples, e.g., in any one or more of operations 300A through 300G, a component (not shown) may be disposed on a surface of the substrate. The component may be similar to the component 127 and may be disposed a horizontal distance of less than about 100 microns from a surface of the feature or a surface of the feature mold, similar to distance 117 in FIG. 1A through FIG. 1C.

In some examples, operation 300H at FIG. 3H may include similar properties to operation 300D. In some examples, operation 300I at FIG. 3I may include similar properties to operation 300E.

For example, in operation 300H and 300I, the material 103 may be generated such that as the diamond substrate thickness grows in the direction indicated by the arrow in region 113, the diamond crystal sizes may increase (e.g., diameter of crystals may increase).

The average crystal grain size (e.g., diameter) of the region 113 may increase in a direction away from an interface between the material 103 and the structure 101, represented by the arrow in region 113. The average crystal grain density of the region 113 may change (e.g., decrease) in a direction away from the interface between the material 103 and the structure 101, represented by the arrow in region 113.

The average crystal grain size of the region 113 may increase generally proportional to a distance away from the interface between the material 103 and the structure 101, represented by the arrow in region 113.

Region 111C and region 111D in operations 300H and 300I may vary from region 111 in operation 300D and 300E, respectively, in that an average crystal grain size (e.g., diameter) of the region 111C and region 111D may not increase in a direction away from a surface of the feature mold 305 (e.g., feature 105, material 201). Instead, the crystal grain size may increase in a direction away from the interface between the material 103 and the structure 101. The crystal grain size may increase in a direction substantially parallel to a surface of the feature (e.g., 305 105, 201), represented by the arrow in region 111C and region 111D in operation 300H and 300I. The average crystal grain size of the region 111C and region 111D may increase generally proportional to a distance away from the interface between the material 103 and the structure 101 and substantially parallel to a surface of the feature (e.g., 305 105, 201).

In some examples, the material 103 may begin growth at a location proximate to the interface between the material 103 and the structure 101 (e.g., begin growth from a surface of the material 101) and the crystal grains may end growth at a location proximate, adjacent to or at a surface of the feature (e.g., 305 105, 201). The crystal grains of the material 103 may form a surface adjacent to the feature (e.g., 305 105, 201) that has a threshold surface roughness (e.g., root mean squared surface roughness). The surface roughness may be from about 20 nanometers to about 10 microns, for example. The surface roughness may be less than 50 microns, less than 30 microns, less than 20 microns, less than 5,000 nanometers, less than 1,000 nanometers, less than 500 nanometers, less than 100 nanometers, less than 50 nanometers, or less than 20 nanometers or less. The material 103 may form a surface adjacent to the feature (e.g., 305, 105, 201) that comprises a plurality of voids (e.g., holes, air pockets) and the voids at an interface between the material 103 and the feature may have diameters that are proportional to the size of the crystal grain sizes. For example, a diameter of the plurality of voids may change (e.g., increase or decrease) with a crystal grain diameter of the material.

Region 111C and region 111D in operations 300H and 300I may vary from region 111 in operation 300D and 300E, respectively, in that an average crystal grain size (e.g., diameter) of the region 111C and region 111D may not increase in a direction away from a surface of the feature mold 305 (e.g., feature 105, material 201). Instead, the crystal grain size may increase in a direction away from the interface between the material 103 and the structure 101.

In some embodiments, the diamond substrate material 103 may be generated by selective area growth. In such embodiments, diamond seeds may be deposited over at least a portion of a surface of the structure 101. For example, the diamond seeds may be deposited around the feature (e.g., 305, 105, 201). The diamond seeds may be deposited such that the feature (e.g., 305, 105, 201) is substantially without diamond seeds on any surface of the feature (e.g., 305, 105, 201).

FIG. 3J-FIG. 3L further illustrates elements relative to operation 405 of FIG. 4 and as illustrated, for example, in operation 300D of FIG. 3D. Referring to FIG. 3J-FIG. 3L, the diamond substrate comprising material 103 may have elements similar to the diamond substrate comprising material 103 in, for example, in operation 300D of FIG. 3D. FIG. 3J-FIG. 3L may illustrate the diamond growth process and the keyhole formation. The diamond substrate comprising material 103 may be generated, for example, at least by (i) seeding the surfaces of the substrate comprising the structure 101 and the feature mold 305 (e.g., material 201) with diamond nano-crystals, (ii) providing the structure 101 in a chamber, such as a chemical vapor deposition chamber, (iii) providing a base pressure in the chamber and a temperature, (iv) introducing a flow of a carrier gas (e.g., argon, hydrogen, etc.) and a flow of a carbon-containing gas (e.g., methane, carbon dioxide, etc.), and (v) striking a plasma in the chamber. In some embodiments, the diamond substrate material 103 may be generated by selective area growth. In such embodiments, diamond seeds may be deposited over at least a portion of a surface of the structure 101. For example, the diamond seeds may be deposited around the feature mold 305. The diamond seeds may be deposited such that the feature mold 305 is substantially without diamond seeds on any surface of the feature mold 305. In some examples of selective area growth, diamond seeds may be deposited on a surface of the feature mold and later removed (e.g., prior to diamond growth).

These operations may not necessarily be in this order. The plasma may break up the carbon-containing gas and carbon molecules may react with a surface of the feature mold 305, or the material 201, causing diamond crystals to grow. As the diamond substrate thickness grows, for example in the directions indicated by arrows in region 111, region 113 and region 131, the diamond crystal sizes may increase (e.g., diameter of crystals may increase).

The average crystal grain size (e.g., diameter) of the region 111 may increase in a direction away from a surface of the feature mold 305 (e.g., arrow in region 111). The average crystal grain density of the region 111 may change (e.g., decrease) in a direction away from a surface of the feature mold 305. The average crystal grain size (e.g., diameter) of the region 113 may increase in a direction away from an interface between the material 103 and the structure 101 (e.g., arrow in region 113). The average crystal grain density of the region 113 may change (e.g., decrease) in a direction away from the interface between the material 103 and the structure 101. The average crystal grain size of the region 111 may increase generally proportional to a distance away from a surface of the feature mold 305. The average crystal grain size of the region 113 may increase generally proportional to a distance away from the interface between the material 103 and the structure 101.

The crystal grain size on a growth front or surface of the material 103 (e.g., 133) may increase generally proportional to a distance from a surface of the feature mold 305 or proportional to a thickness of the material 103 grown as measured from the surface of the feature mold 305 to the growth front 133. The direction of growth may be perpendicular from the surface of the feature mold 305. The crystal grain size (e.g., diameter) on a growth front or surface of the material 103 (e.g., 133) may be approximately 1/10^{th} of the thickness of the material 103 grown as measured from the surface of the feature mold 305 to the growth front 133.

For example, the average crystal grain diameter of crystal grains in the region 111 may be about 0.5 microns at a location about 5 microns from a surface of the feature mold 305. As the material 103 grows in a direction away from a surface of the feature mold 305, crystal grain sizes on the growth front 133 may be 1/10^{th} the thickness of the total grown material 103 as measured from a surface of the feature mold 305 to the location of the growth front 133. The same relationship of crystal grain size to material thickness may exist in region 113.

During the diamond growth process, a keyhole may form in the diamond substrate. This is illustrated in operations 301D through 301F. As shown in 301D of FIG. 3J, the diamond begins to form after being exposed to the diamond growth conditions (e.g., reactive species in the plasma, gases, etc.) in the chamber. However, the diamond may only grow if the growth front 133 or surface of the material 103 is exposed to the diamond growth conditions. As shown in operation 301E of FIG. 3K, an area 135 between the growth front 133A and the growth front 133B begins to close as the interior of the area 135 is less exposed to the diamond growth conditions. As shown in operation 301F of FIG. 3L, the area 135 has closed because of lack of exposure to the diamond growth conditions and the growth fronts 133A and 133B continue growing and forming diamond material 103. This process may form keyhole 129 as shown to the right of the feature mold 305.

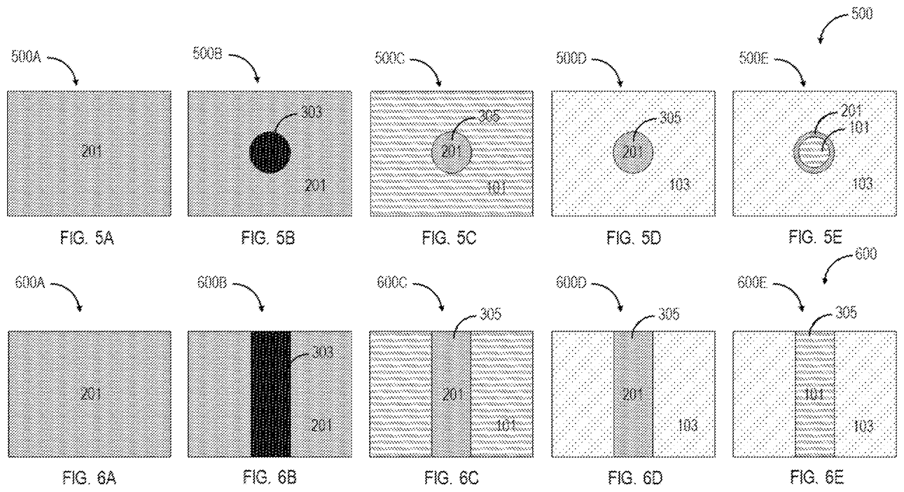

FIG. 5A-FIG. 5E illustrate generally a flow diagram of an example method 500 of generating a feature in a substrate, in accordance with some examples. FIG. 6A-FIG. 6E illustrates generally a flow diagram of another example method 600 of generating a feature in a substrate, in accordance with some examples. FIG. 5A-FIG. 5E and FIG. 6A-FIG. 6E may each be a top-down view of a substrate. The method 500 may have one or more elements similar to one or more elements of method 300 of FIG. 3. The method 600 may have one or more elements similar to one or more elements of method 3 of FIG. 3.

FIG. 5A-FIG. 5E, in operation 500A of FIG. 5A, a substrate is provided. The substrate may include a structure 101 (not shown in operation 500A, but shown in operation 500C), such as a layered semiconductor-containing structure as described herein. The substrate may further include a material 201, which may be disposed over the structure.

In operation 500B of FIG. 5B, an etch mask 303 is disposed over a surface of the substrate. The etch mask 303 may be formed to etch one or more round-shaped features, such as a round interconnect or via. The etch mask 303 may be formed to etch one or more rectangular-shaped features, such as a rectangular interconnect, via, channel or die street.

In operation 500C of FIG. 5C, at least a portion of the material 201 is etched. The etching of material 201 exposes at least a portion of the structure 101. The etching of material 201 may form a feature mold 305. The feature mold 305 may be a feature mold as described herein.

In operation 500D of FIG. 5D, a material 103 is generated over a surface of the structure 101. The material may be a high-thermal conductivity as described herein, for example, having a thermal conductivity of equal to or greater than about 1,000 W/mK. The material 103 may be diamond and may have a thickness of about 100 microns. The material 103 may comprise a region of crystal grains having an average crystal grain diameter from about 10 nm to about 100 nm, and the region may be disposed a distance of less than or equal to about 100 microns from a surface of the substrate mold 305.

The material 103 may comprise a keyhole or void, and the keyhole or void may be disposed a distance of less than or equal to about 100 microns from a surface of an interface between the material 103 and the material 201 or an inside surface of the material 201 (e.g., in a hollow region).

In operation 500E of FIG. 5E, at least a portion of the substrate mold 305 is etched. In some examples, a portion of the material 201 of the substrate mold 305 remains after etching. The etching of material 201 may expose a hollow portion in material 201 and/or material 103. The etching of material 201 may expose a portion of the structure 101. At least a portion of the structure 101 may be etched to generate an additional hollow region. The hollow region in one or more of the material 201, material 103 and structure 101 may be plated.

Referring to FIG. 6A-FIG. 6E, in operation 600A of FIG. 6A, a substrate is provided. The substrate may include a structure 101 (not shown in operation 600A, but shown in operation 600C), such as a layered semiconductor-containing structure as described herein. The substrate may further include a material 201, which may be disposed over the structure.

In operation 600B of FIG. 6B, an etch mask 303 is disposed over a surface of the substrate. The etch mask 303 may be formed to etch one or more features that may be a channel or die street. The etch mask 303 may be formed to etch one or more rectangular-shaped features. The etch mask 303 may be formed to etch a perforated channel, for example, comprising a path of one or more etched regions of the material 201 and one or more un-etched regions of the material 201. The regions may alternate in position along the path of the channel. A channel or die street may be used for wafer singulation, for example.

In operation 600C of FIG. 6C, at least a portion of the material 201 is etched. The etching of material 201 exposes at least a portion of the structure 101. The etching of material 201 may form a feature mold 305. The feature mold 305 may be a feature mold as described herein.

In operation 600D of FIG. 6D, a material 103 is generated over a surface of the structure 101. The material may be a high-thermal conductivity as described herein, for example, having a thermal conductivity of equal to or greater than about 1,000 W/mK. The material 103 may be diamond and may have a thickness of less than about 600 microns (e.g., about 100 microns). The material 103 may comprise a region of crystal grains having an average crystal grain diameter from about 10 nm to about 2,000 nm, and the region may be disposed a distance of less than or equal to about 100 microns from a surface of the substrate mold 305. The material 103 may comprise a keyhole or void, and the keyhole or void may be disposed a distance of less than or equal to about 100 microns from a surface of an interface between the material 103 and the material 201 or an inside surface of the material 103 (e.g., in a hollow region).

In operation 600E of FIG. 6E, at least a portion of the substrate mold 305 is etched. In some examples, a portion of the material 201 of the substrate mold 305 remains after etching (not shown in operation 600E). The etching of material 201 may expose a hollow portion in material 201 and/or material 103. The etching of material 201 may expose a portion of the structure 101. At least a portion of the structure 101 may be etched to generate an additional hollow region. The hollow region in one or more of the material 201, material 103 and structure 101 may be plated.

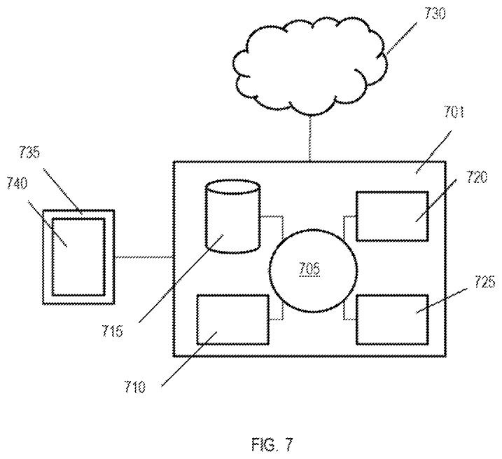

The present disclosure provides examples of computer systems that can be programmed to implement methods of the disclosure, such as methods for generating features in substrates, as disclosed herein. FIG. 7 illustrates a computer system 701 that can be programmed or otherwise configured to form an example device, in accordance with some examples. The computer system 701 may be used to control one or more tools that can be used for forming a layered structure. The tools may include, for example a deposition chamber, an etching chamber, lithography equipment, chemical baths, cleaning chambers, and any other equipment associated with semiconductor, wafer level, or thin film processing.

The computer system 701 includes a central processing unit (CPU, also “processor” and “computer processor” herein) 705, which can be a single core or multi core processor, or a plurality of processors for parallel processing. The computer system 701 also includes memory or memory location 710 (e.g., random-access memory, read-only memory, flash memory), electronic storage unit 715 (e.g., hard disk), communication interface 720 (e.g., network adapter) for communicating with one or more other systems, and peripheral devices 725, such as cache, other memory, data storage and/or electronic display adapters. The memory 710, storage unit 715, interface 720 and peripheral devices 725 are in communication with the CPU 705 through a communication bus (solid lines), such as a motherboard. The storage unit 715 can be a data storage unit (or data repository) for storing data. The computer system 701 can be operatively coupled to a computer network (“network”) 730 with the aid of the communication interface 720. The network 730 can be the Internet, an internet and/or extranet, or an intranet and/or extranet that is in communication with the Internet. The network 730 in some cases is a telecommunication and/or data network. The network 730 can include one or more computer servers, which can enable distributed computing, such as cloud computing. The network 730, in some cases with the aid of the computer system 701, can implement a peer-to-peer network, which may enable devices coupled to the computer system 701 to behave as a client or a server. The CPU 705 can execute a sequence of machine-readable instructions, which can be embodied in a program or software. The instructions may be stored in a memory location, such as the memory 710. The instructions can be directed to the CPU 705, which can subsequently program or otherwise configure the CPU 705 to implement methods of the present disclosure. Examples of operations performed by the CPU 705 can include fetch, decode, execute, and writeback.

The CPU 705 can be part of a circuit, such as an integrated circuit. One or more other components of the system 701 can be included in the circuit. In some cases, the circuit is an application specific integrated circuit (ASIC). The storage unit 715 can store files, such as drivers, libraries and saved programs. The storage unit 715 can store user data, e.g., user preferences and user programs. The computer system 701 in some cases can include one or more additional data storage units that are external to the computer system 701, such as located on a remote server that is in communication with the computer system 701 through an intranet or the Internet. The computer system 701 can communicate with one or more remote computer systems through the network 730. For instance, the computer system 701 can communicate with a remote computer system of a user. Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. The user can access the computer system 701 via the network 730. Methods as described herein can be implemented by way of machine (e.g., computer processor) executable code stored on an electronic storage location of the computer system 701, such as, for example, on the memory 710 or electronic storage unit 715. The machine executable or machine-readable code can be provided in the form of software. During use, the code can be executed by the processor 705. In some cases, the code can be retrieved from the storage unit 715 and stored on the memory 710 for ready access by the processor 705. In some situations, the electronic storage unit 715 can be precluded, and machine-executable instructions are stored on memory 710.

The code can be pre-compiled and configured for use with a machine having a processer adapted to execute the code or can be compiled during runtime. The code can be supplied in a programming language that can be selected to enable the code to execute in a pre-compiled or as-compiled fashion. Examples of the systems and methods provided herein, such as the computer system 701, can be embodied in programming. Various examples of the technology may be thought of as “products” or “articles of manufacture” typically in the form of machine (or processor) executable code and/or associated data that is carried on or embodied in a type of machine readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution. The computer system 701 can include or be in communication with an electronic display 735 that comprises a user interface (UI) 740. Examples of UI's include, without limitation, a graphical user interface (GUI) and web-based user interface. Methods and systems of the present disclosure can be implemented by way of one or more algorithms. An algorithm can be implemented by way of software upon execution by the central processing unit 705.

While preferred examples of the present disclosure have been shown and described herein, it will be obvious to those skilled in the art that such examples are provided by way of example only. It is not intended that the present disclosure be limited by the specific examples provided within the specification. While the present disclosure has been described with reference to the aforementioned specification, the descriptions and illustrations of the examples herein are not meant to be construed in a limiting sense. Numerous variations, changes, and substitutions will now occur to those skilled in the art without departing from the present disclosure. Furthermore, it shall be understood that all examples of the present disclosure are not limited to the specific depictions, configurations or relative proportions set forth herein which depend upon a variety of conditions and variables. It should be understood that various alternatives to the examples of the present disclosure described herein may be employed in practicing the present disclosure. It is therefore contemplated that the present disclosure shall also cover any such alternatives, modifications, variations or equivalents. It is intended that the following claims define the scope of the present disclosure and that methods and structures within the scope of these claims and their equivalents be covered thereby.

What is claimed is:

1. A semiconductor structure comprising:
a layered structure comprising a semiconductor material;
a layer of material on the layered structure; and
a substrate feature extending into at least a portion of the layer of material,
wherein a region of the layer of material in proximity to the substrate feature comprises a plurality of crystals having an average grain size or an average grain density that is different from another region of the layer of material that is further away from the substrate feature than the region.

2. The semiconductor structure of claim 1, wherein at least a portion of the plurality of crystals is at a distance of less than or equal to about 100 micrometers from the substrate feature, wherein the substrate feature is an interconnect.

3. The semiconductor structure of claim 1, wherein at least a portion of the plurality of crystals is at a distance of less than or equal to about 100 micrometers from an edge of the semiconductor structure.

4. The semiconductor structure of claim 1, wherein the layer of material comprises a keyhole, and wherein the keyhole is disposed within the layer of material at a distance of less than or equal to about 100 micrometers from the substrate feature.

5. The semiconductor structure of claim 1, wherein the average grain size of the plurality of crystals increases with distance in a direction away from the substrate feature.

6. The semiconductor structure of claim 1, wherein a region of the layer of material in proximity to an interface between the layer of material and the layered structure comprises a plurality of crystals having an average grain size or an average grain density that is different from another region of the layer of material that is further away from the interface.

7. The semiconductor structure of claim 6, wherein at least a portion of the plurality of crystals is at a distance of less than or equal to about 100 micrometers from the interface.

8. The semiconductor structure of claim 6, wherein the average grain size of the plurality of crystals increases with distance in a direction away from the interface or increases in a direction parallel to a surface of the substrate feature.

9. The semiconductor structure of claim 6, wherein at least a portion of the plurality of crystals forms a surface adjacent to the substrate feature having a surface roughness from about 20 nanometers to about 10 microns.

10. The semiconductor structure of claim 9, wherein at least a portion of the surface comprises a plurality of voids in the material wherein a diameter of the plurality of voids varies in proportion with the average grain size of the material.

11. The semiconductor structure of claim 1, wherein the average grain size is an average crystal grain diameter, and the average crystal grain diameter of the plurality of crystals is from about 10 nanometers to about 2,000 nanometers.

12. The semiconductor structure of claim 1, wherein the semiconductor material is a wide-bandgap semiconductor material.

13. The semiconductor structure of claim 1, wherein the substrate feature is a die street, a via, or a trench.

14. The semiconductor structure of claim 1, wherein the substrate feature is at the edge of the semiconductor structure.

15. The semiconductor structure of claim 1, further comprising at least one device on the layered structure or the layer of material.

16. The semiconductor structure of claim 15, wherein the at least one device is at a distance less than or equal to about 100 micrometers from the substrate feature.

17. The semiconductor structure of claim 1, wherein the layer of material comprises diamond.

18. The semiconductor structure of claim 1, wherein the substrate feature comprises silicon.

19. A method for generating a layer of diamond comprising a hole, the method comprising
(a) providing a support and a post over said support;
(b) growing a layer of diamond over said support, wherein said layer of diamond circumscribes said post; and
(c) removing said post, thereby yielding said layer of diamond comprising said hole.

20. A method comprising:
(i) providing a first semiconductor material layer and a second semiconductor material layer;
(ii) etching the second semiconductor material layer to form a feature mold;
(iii) generating, over a surface of the first semiconductor material, a layer of material; and
(iv) etching at least a portion of the feature mold to generate a substrate feature comprising a hollow region, wherein a region of the layer of material in proximity to the substrate feature comprises a plurality of crystals having an average grain size or an average grain density that is different from another region of the layer of material that is further away from the substrate feature than the region.
